(19) United States
(12) Patent Application Publication
(10) Pub. No.: US 2026/0020408 A1
(43) Pub. Date: Jan. 15, 2026

(54) Display Panel, Display Device, and Tiled Display Device

(71) Applicants: BOE MLED Technology Co., Ltd., Beijing (CN); BOE TECHNOLOGY GROUP CO., LTD., Chaoyang District, Beijing (CN)

(72) Inventors: Lili Wang, Beijing (CN); Jingping Zhao, Beijing (CN); Shanshan Feng, Beijing (CN); Mengqing Liu, Beijing (CN); Huaimin Wang, Beijing (CN); Jing Wang, Beijing (CN); Mingming Jia, Beijing (CN); Chao Liu, Beijing (CN); Ming Zhai, Beijing (CN); Qi Qi, Beijing (CN)

(21) Appl. No.: 18/993,750

(22) PCT Filed: May 16, 2023
(86) PCT No.: PCT/CN2023/094543

§ 371 Date: Jan. 13, 2025

(51) Int. Cl. H10H 29/49

(52) U.S. Cl. CPC H10H 29/49

(57) ABSTRACT

A display panel includes a substrate, a bridge structure, back electrodes, and connecting leads. The substrate includes first and second surfaces, and at least one selected first side surface. The bridge structure includes third and fourth surfaces, and at least one selected second side surface. The third and fourth surfaces have a first spacing. Each connecting lead includes first, second and third portions respectively on sides of the first surface, the selected first side surface, and the second surface. The third part includes portions respectively on the second surface, the selected second side surface, and a side of the fourth surface. On the third surface, an orthographic projection of a first common edge between the selected second side surface and the fourth surface and an orthographic projection of a second common edge between the selected second side surface and the third surface have a second spacing.

### CROSS-REFERENCE TO RELATED APPLICATION

This application is the United States national phase of International Patent Application No. PCT/CN2023/094543, filed May 16, 2023, the disclosure of which is hereby incorporated by reference in its entirety.

### BACKGROUND OF THE INVENTION

### Field of the Invention

The present disclosure relates to the field of display technologies, and in particular, to a display panel, a display device, and a tiled display device.

### Description of Related Art

Compared to traditional light-emitting diodes (LEDs), the micro light-emitting diode (Micro LED) and mini light-emitting diode (Mini LED) have smaller particles, i.e., smaller volumes, and are widely used in display devices to form Micro LED/Mini LED display devices with high display effects.

### SUMMARY OF THE INVENTION

In an aspect, a display panel is provided, which includes a substrate, a bridge structure, a plurality of back electrodes, and a plurality of connecting leads. The substrate includes a first surface and a second surface arranged oppositely, and a plurality of first side surfaces connecting the first surface and the second surface, where the plurality of first side surfaces include at least one selected first side surface. The bridge structure is disposed on the second surface and includes a third surface and a fourth surface arranged oppositely, and a plurality of second side surfaces connecting the third surface and the fourth surface, the third surface being closer to the substrate than the fourth surface, where the plurality of second side surfaces include at least one selected second side surface, and each selected second side surface corresponds to one selected first side surface; and the third surface and the fourth surface have a first spacing. The plurality of back electrodes are arranged side by side at intervals on the fourth surface. The plurality of connecting leads are arranged side by side at intervals, where each connecting lead includes a first portion located on a side of the first surface, a second portion located on a side of the selected first side surface, and a third portion located on a side of the second surface; and the third part of each connecting lead is electrically connected to one back electrode, and the third part of the connecting lead includes a portion located on the second surface, a portion located on the selected second side surface, and a portion located on a side of the fourth surface. A first common edge is an intersection line of the selected second side surface and the fourth surface, and a second common edge is an intersection line of the selected second side surface and the third surface; and an orthographic projection of the first common edge on the third surface and an orthographic projection of the second common edge on the third surface have a second spacing, and a ratio of the first spacing to the second spacing is in a range of 0.27 to 1.73; and a distance between the second common edge and the selected first side surface is a third spacing, and a value of the third spacing is in a range of 0.5 mm to 2.0 mm.

In some embodiments, the portion of the third part of the connecting lead corresponding to the fourth surface has a first thickness, the portion of the third part of the connecting lead corresponding to the second surface has a second thickness, and the portion of the third part of the connecting lead corresponding to the selected second side surface has a third thickness. The first thickness is greater than or equal to the second thickness, and a difference between the first thickness and the second thickness is in a range of 0 to 1 μm; and the third thickness is greater than the first thickness or the second thickness, and a difference between the third thickness and the first thickness, or a difference between the third thickness and the second thickness is in a range of 1 μm to 3 μm.

In some embodiments, a section of the selected second side surface perpendicular to the first common edge or the second common edge is in a shape of a straight segment, a curved segment, or a polyline segment, the curved segment being bent away from the second surface.

In some embodiments, the selected second side surface is a plane, and an included angle between the selected second side surface and the third surface is in a range of 10° to 80°.

In some embodiments, the selected second side surface includes a plurality of sub-surfaces connected in sequence. In two adjacent sub-surfaces, a sub-surface further away from the selected first side surface is further away from the second surface than the other sub-surface.

In some embodiments, the plurality of sub-surfaces are planes, and the selected second side surface is in a stepped shape; and the plurality of sub-surfaces of the selected second side surface include at least two first sub-surfaces and at least one second sub-surface that are arranged alternately; and in the plurality of sub-surfaces, a sub-surface closest to the fourth surface and a sub-surface closest to the second surface are both first sub-surfaces. The at least two first sub-surfaces are parallel to the selected first side surface; and/or the at least one second sub-surface is parallel to the second surface.

In some embodiments, in a first direction, a dimension of an orthographic projection of each of the at least two first sub-surfaces on a first reference plane is a first dimension, the first reference plane being parallel to the selected first side surface, and the first direction being a thickness direction of the substrate; and/or in a third direction, a dimension of an orthographic projection of the at least one second sub-surface on a second reference plane is a second dimension, the second reference plane being parallel to the second surface, and the third direction being perpendicular to the selected first side surface.

In some embodiments, the bridge structure includes a circuit board, including a fifth surface and a sixth surface arranged oppositely, and a plurality of third side surfaces connecting the fifth surface and the sixth surface, where the plurality of third side surfaces include at least one selected third side surface, the at least one selected third side surface serving as the at least one selected second side surface; and the plurality of back electrodes are arranged side by side at intervals on the sixth surface.

In some embodiments, the circuit board includes an adhesive layer and a carrier board body disposed in stack, the adhesive layer being closer to the substrate than the carrier board body; and the selected third side surface of the circuit board is in a stepped shape, and a distance between an end of the carrier board body proximate to the selected first side surface and the selected first side surface is greater than a distance between an end of the adhesive layer proximate to the selected first side surface and the selected first side surface.

In some embodiments, a ratio of a thickness of the adhesive layer to a thickness of the carrier board body is in a range of 1.4 to 1.6.

In some embodiments, the bridge structure includes a circuit board and a buffer structure. The circuit board includes a fifth surface and a sixth surface arranged oppositely, and a plurality of third side surfaces connecting the fifth surface and the sixth surface, where the plurality of back electrodes are arranged side by side at intervals on the sixth surface. The buffer structure is located on a side of the circuit board proximate to the selected first side surface, where an outer surface of the buffer structure serves as at least a portion of the selected second side surface, and the outer surface of the buffer structure is a surface of the buffer structure away from the circuit board and the second surface.

In some embodiments, the buffer structure includes a plurality of first buffer sub-structures, and at least a portion of each connecting lead is disposed on a corresponding first buffer sub-structure of the plurality of first buffer sub-structures.

In some embodiments, the plurality of connecting leads include multiple groups of connecting leads, each group of connecting leads including at least two connecting leads; and the buffer structure includes a plurality of second buffer sub-structures, and at least a portion of each group of connecting leads is disposed on a corresponding second buffer sub-structure in the plurality of second buffer sub-structures.

In some embodiments, the buffer structure extends along a second direction, the second direction being an extension direction of a boundary line between the selected first side surface and the second surface; and a length of the buffer structure is greater than a distance between outer side edges of two connecting leads of the plurality of connecting leads whose orthographic projections on the second surface are located outermost, the outer side edges of the two connecting leads being side edges of the two connecting leads away from each other.

In some embodiments, a section, perpendicular to the first common edge or the second common edge, of a surface of the buffer structure away from the circuit board and the second surface is in a shape of a straight segment, a curved segment or a polyline segment, the curved segment being bent away from the second surface; or the surface of the buffer structure away from the circuit board and the second surface includes a plurality of sub-surfaces connected in sequence.

In some embodiments, the buffer structure covers a junction of a side surface of the circuit board proximate to the selected first side surface and the sixth surface of the circuit board.

In some embodiments, a material of the buffer structure includes an organic material.

In some embodiments, the portion of the connecting lead located on the second surface has an end proximate to the bridge structure, and a dimension of the end in a second direction is greater than dimensions of the remaining portions of the connecting lead in the second direction, the second direction being an extension direction of a boundary line between the selected first side surface and the second surface.

In some embodiments, each back electrode includes a first straight part, a diagonal part, and a second straight part. The first straight part extends along a direction perpendicular to a second direction, the second direction being an extension direction of a boundary line between the selected first side surface and the second surface. The diagonal part is connected to the first straight part, the extension direction of the first straight part intersecting an extension direction of the diagonal part. The second straight part is connected to the diagonal part and extends along the direction perpendicular to the second direction, the second straight part being further away from the selected first side surface than the first straight part. The first straight part is electrically connected to a third part of a connecting lead, and the second straight part is configured to connect a flexible circuit board; and first straight parts of the plurality of back electrodes are arranged along the second direction, second straight parts of the plurality of back electrodes are arranged along the second direction, and a dimension of the second straight parts along the second direction is less than a dimension of the first straight parts along the second direction.

In another aspect, a display device is provided, which includes the display panel as described in any of the embodiments, and a driving circuit board. The driving circuit board is electrically connected to the display panel and configured to drive the display panel to display an image.

In yet another aspect, a titled display device is provided, which includes a plurality of display devices each as described in any of the embodiments.

### BRIEF DESCRIPTION OF THE DRAWINGS

In order to describe technical solutions in the present disclosure more clearly, the accompanying drawings to be used in some embodiments of the present disclosure will be introduced briefly; obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display panel, in accordance with some embodiments;

FIG. 2 is a structural diagram of a display panel, in accordance with some other embodiments;

FIG. 3 is a flow chart of a manufacturing process of a display panel, in accordance with some embodiments;

FIG. 4 is a structural diagram of a display panel, in accordance with yet some other embodiments;

FIG. 5 is a structural diagram of a display panel, in accordance with still some other embodiments;

FIG. 6 is a partially enlarged view of the region J in FIG. 4;

FIG. 7A is a structural diagram of a bridge structure, in accordance with some embodiments;

FIG. 7B is a structural diagram of a bridge structure, in accordance with some other embodiments;

FIG. 7C is a structural diagram of a bridge structure, in accordance with yet some other embodiments;

FIG. 7D is a structural diagram of a bridge structure, in accordance with still some other embodiments;

FIG. 7E is a structural diagram of a bridge structure, in accordance with still yet some other embodiments;

FIG. 7F is a structural diagram of a bridge structure, in accordance with still yet some other embodiments;

FIG. 8 is a structural diagram of a bridge structure, in accordance with still yet some other embodiments;

FIG. 9 is a structural diagram of a display panel, in accordance with still yet some other embodiments;

FIG. 10 is a structural diagram of a bridge structure, in accordance with still yet some other embodiments;

FIG. 11 is a structural diagram of a bridge structure, in accordance with still yet some other embodiments;

FIG. 12 is a structural diagram of a bridge structure, in accordance with still yet some other embodiments;

FIG. 13A is a structural diagram of a bridge structure, in accordance with still yet some other embodiments;

FIG. 13B is a structural diagram of a bridge structure, in accordance with still yet some other embodiments;

FIG. 13C is a structural diagram of a bridge structure, in accordance with still yet some other embodiments;

FIG. 13D is a structural diagram of a bridge structure, in accordance with still yet some other embodiments;

FIG. 14 is a structural diagram of a display panel, in accordance with still yet some other embodiments;

FIG. 15 is a structural diagram of a display panel, in accordance with still yet some other embodiments;

FIG. 16 is a structural diagram of a display panel, in accordance with still yet some other embodiments;

FIG. 17A is a structural diagram of a bridge structure, in accordance with still yet some other embodiments;

FIG. 17B is a structural diagram of a bridge structure, in accordance with still yet some other embodiments;

FIG. 17C is a structural diagram of a bridge structure, in accordance with still yet some other embodiments;

FIG. 18 is a structural diagram of a display panel, in accordance with still yet some other embodiments;

FIG. 19 is a structural diagram of a bridge structure, in accordance with still yet some other embodiments;

FIG. 20 is a structural diagram of a display panel, in accordance with still yet some other embodiments;

FIG. 21 is a structural diagram of a bridge structure, in accordance with still yet some other embodiments;

FIG. 22A is a structural diagram of a display device, in accordance with some embodiments;

FIG. 22B is a structural diagram of a display device, in accordance with some other embodiments;

FIG. 23 is a structural diagram of a display panel, in accordance with yet some other embodiments;

FIG. 24 is a structural diagram of a tiled display device, in accordance with some embodiments;

FIG. 25 is a structural diagram of a display panel, in accordance with still yet some other embodiments;

FIG. 26 is a structural diagram of a tiled display device, in accordance with some other embodiments; and

FIG. 27 is a flow chart of a manufacturing process of a display panel, in accordance with some other embodiments.

### DESCRIPTION OF THE INVENTION

The technical solutions in some embodiments of the present disclosure will be described clearly and completely with reference to the accompanying drawings. Obviously, the described embodiments are merely some but not all of embodiments of the present disclosure. All other embodiments obtained on the basis of the embodiments of the present disclosure by a person of ordinary skill in the art shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to.” In the description of the specification, terms such as “one embodiment,” “some embodiments,” “exemplary embodiments,” “example,” “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, specific features, structures, materials, or characteristics described herein may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a/the plurality of (multiple)” means two or more unless otherwise specified.

The terms “coupled,” “connected” and their derivatives may be used in the description of some embodiments. For example, the term “connected” may be used in the description of some embodiments to indicate that two or more components are in direct physical or electrical contact with each other. As another example, the term “coupled” may be used in the description of some embodiments to indicate that two or more components are in direct physical or electrical contact. However, the term “coupled” or “communicatively coupled” may also indicate that two or more components are not in direct contact with each other, but still cooperate or interact with each other. The embodiments disclosed herein are not necessarily limited to the context herein.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

The term such as “parallel,” “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It should be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the drawings, thicknesses of layers and dimensions of regions/areas are enlarged for clarity. Variations in shapes than the accompanying drawings due to, for example, manufacturing technologies and/or tolerances may be envisaged. Therefore, the exemplary embodiments should not be construed to be limited to the shapes of regions shown herein, but to include deviations in the shapes due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

It will be noted that the symbol “11˜1” appearing in the drawings of present disclosure indicates that a component 11 belongs to a component 1, and the symbol “1b˜1” indicates that a second surface 1b belongs to a substrate 1, and other similar symbols appearing in the drawings of present disclosure also follow the above description; and the symbol “1/2” appearing in the drawings of the present disclosure indicates that both a plane 1 and a plane 2 can refer to a plane, for example, the symbol “81cc/8cc” in the drawings indicates that both a selected third side surface 81cc and a selected second side surface 8cc can be represented by a plane, and other similar symbols appearing in the drawings also follow the above description.

In order to improve product reliability and reduce transportation and maintenance costs, a large-size display device may be assembled by splicing a plurality of small-size display devices.

In order to avoid the fragmentation of a display image caused by splicing, it is necessary to reduce a frame size of a single small-size display device to reduce the width of a splicing seam. The small-size display device includes a display panel. For example, lines located on a side of a display surface of the display panel may be connected, through side wiring, to a circuit board (e.g., a flexible circuit board) provided on a side of a non-display surface of the display panel, so that when a plurality of small-size display devices are spliced to form a large-size display device, a distance between adjacent small-size display devices may be smaller, thereby reducing the splicing seam width of the large-size display device formed by splicing the plurality of small-size display devices to improve the display quality.

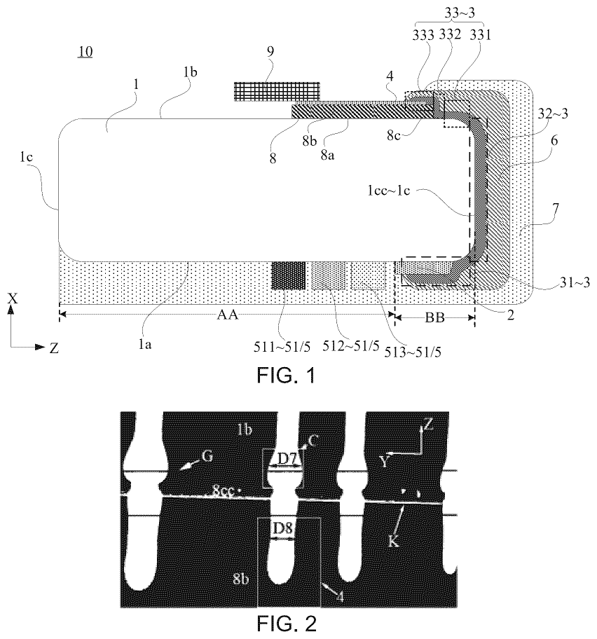

As shown in FIGS. 1, 2, 4 and 5, in some embodiments, the display panel 10 includes a substrate 1, a plurality of front electrodes 2, a plurality of connecting leads 3, and a plurality of back electrodes 4. The substrate 1 includes a first surface 1a and a second surface 1b arranged oppositely, and a plurality of first side surfaces 1c connecting the first surface 1a and the second surface 1b. At least one first side surface 1c of the plurality of first side surfaces 1c of the substrate 1 is a selected first side surface 1cc. Each selected first side surface 1cc is correspondingly provided with multiple connecting leads 3, and the multiple connecting leads 3 are arranged side by side at intervals. Each connecting lead extends from the first surface, through the selected first side surface 1cc, to the second surface. That is to say, each connecting lead 3 includes a first part 31 located on a side of the first surface 1a, a second part 32 located on a side of the selected first side surface 1cc, and a third part 33 located on a side of the second surface 1b.

For example, as shown in FIG. 1, a side of the first surface 1a of the substrate 1 is a front side of the display panel 10, and the side of the first surface 1a of the substrate 1 is provided with a display area AA and a bonding area BB. The display area AA is provided with film layer structures such as a driving circuit layer and a light-emitting device layer 5. The light-emitting device layer 5 includes light-emitting devices 51 of at least three colors, the light-emitting devices of the multiple colors include at least light-emitting devices 511 of a first color, light-emitting devices 512 of a second color, and light-emitting devices 513 of a third color. The first color, the second color and the third color are three primary colors (e.g., red, green and blue). For example, the light-emitting device 51 is a micro light-emitting diode (Micro LED) or a mini light-emitting diode display (Mini LED).

As shown in FIGS. 1 and 5, a side of the first surface 1a of the substrate 1 is a front side of the display panel 10. The plurality of front electrodes 2 may be disposed in the bonding area BB and arranged side by side at intervals along a second direction Y, where the second direction Y is a direction parallel to a boundary line between the selected first side surface 1cc and the first surface 1a. The plurality of front electrodes 2 are electrically connected to at least a portion of the driving circuit layer (not shown in the drawings). First parts 31 of the plurality of connecting leads 3 are located on a side of the first surface 1a of the substrate 1 and are electrically connected to the plurality of front electrodes 2 in one-to-one correspondence. An extension direction of the first parts 31 of the plurality of connecting leads 3 is, for example, a direction perpendicular to the selected first side surface 1cc of the substrate 1, i.e., a third direction Z shown in FIG. 1.

For example, as shown in FIGS. 1 and 5, a side of the second surface 1b of the substrate 1 is a back side of the display panel 10, and third parts 33 of the plurality of connecting leads 3 are located on the side of the second surface 1b of the substrate 1, that is to say, the third part 33 of each connecting lead 3 is a portion of the connecting lead 3 located on the back side of the display panel 10. An extension direction of the third parts 33 of the plurality of connecting leads 3 is, for example, the third direction Z. The plurality of back electrodes 4 are disposed on the side of the second surface 1b of the substrate 1 and are arranged side by side at intervals along the second direction Y. The plurality of back electrodes 4 may serve as bonding electrodes for connecting a flexible circuit board 9, and the third parts 33 of the plurality of connecting leads 3 are electrically connected to the plurality of back electrodes 4 in one-to-one correspondence.

In some examples, as shown in FIG. 1, the display panel 10 further includes a protective layer 6 and a light-blocking layer 7. The protective layer 6 covers side surfaces of the connecting leads 3 and is configured to provide an all-round protective effect to the connecting lead 3, avoiding water-oxygen corrosion of the connecting lead 3 due to contact with air and/or water vapor, which may affect the electrical conductivity of the connecting leads 3. The light-blocking layer 7 covers a side of the protective layer 6 away from the connecting leads 3 and a side of the first surface 1a of the substrate 1. In an aspect, the light-blocking layer 7 is configured to prevent external light from entering the display area AA and affecting the display effect; and in another aspect, the light-blocking layer 7 can prevent light emitted by the light-emitting device layer 5 from leaking at splicing seams of the tiled display device.

A manufacturing method of the display panel 10 includes: forming a plurality of front electrodes 2 and a driving circuit layer on a side of a first surface 1a of a substrate 1, and forming a plurality of back electrodes 4 on a side of a second surface 1b of the substrate 1, in which a process of forming the plurality of front electrodes 2 and the driving circuit layer is, for example, an etching process; and a process of forming the plurality of back electrodes 4 is, for example, a laser etching.

In this case, etching is required on both the first surface 1a and the second surface 1b of the substrate 1, resulting in a high manufacturing cost of the display panel 10. Moreover, in a case where orthographic projections of the plurality of back electrodes 4 on the substrate 1 overlap with a region corresponding to the display area AA, the laser may pass through the substrate 1 and be incident within the display area AA of the first surface 1a. As a result, part of the energy of the laser will pass through the substrate 1 and reach the display area AA to cause damage to the film layers and devices in the display area AA, resulting in reliability problems such as localized corrosion, and failure of the light-emitting device to be brightened.

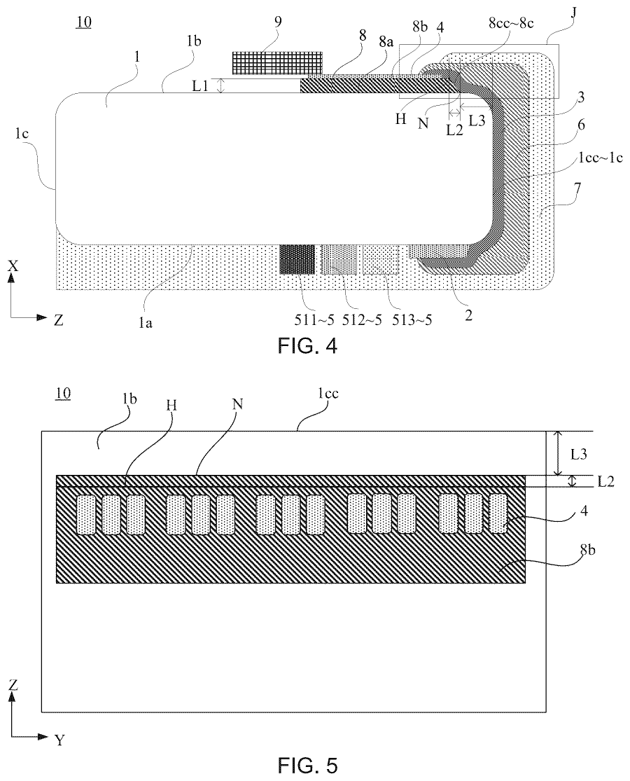

Therefore, in order to reduce the manufacturing cost of the display panel 10 and avoid the impact of the back process for the substrate 1 on the front film layers and devices, in some embodiments, as shown in FIGS. 1 and 4, the display panel 10 further includes a bridge structure 8 disposed on the second surface 1b of the substrate 1. The bridge structure 8 includes a third surface 8a and a fourth surface 8b arranged oppositely, and a plurality of second side surfaces 8c connecting the third surface 8a and the fourth surface 8b, where the third surface 8a is closer to the substrate 1 than the fourth surface 8b. The plurality of second side surfaces 8c include at least one selected second side surface 8cc, and each selected second side surface 8cc corresponds to one selected first side surface 1cc. The plurality of back electrodes 4 are arranged side by side at intervals on the fourth surface 8b.

For example, the thickness of the bridge structure 8 along a first direction X is in a range of 20 μm to 200 μm, where the first direction X is a thickness direction of the substrate 1.

By arranging the bridge structure 8 on the second surface 1b of the substrate 1, the bridge structure 8 can serve as a carrier for the plurality of back electrodes 4. In a case where the display panel 10 includes the bridge structure 8, forming the plurality of back electrodes 4 may be achieved through the following two steps: first forming the plurality of back electrodes 4 on the fourth surface 8b of the bridge structure 8, and then connecting the bridge structure 8 to the second surface 1b of the substrate 1 with high precision, enabling the second surface 1b of the substrate 1 to be in contact with the third surface 8a of the bridge structure 8, and enabling the front electrodes 2 to be directly opposite to the back electrodes 4 in the first direction X. The process of connecting the bridge structure 8 to the second surface 1b of the substrate 1 with high precision is, for example, bonding. The cost may be reduced and the impact of the etching process on the front film layers and the devices may be avoided through the above method.

It will be noted that each selected second side surface 8cc corresponds to one selected first side surface 1cc, which means that the number of selected second side surfaces 8cc corresponds to the number of selected first side surfaces 1cc, and a selected second side surface 8cc is proximate to a selected first side surface 1cc corresponding thereto, and are both arranged along the first direction X.

It can be understood that as shown in FIGS. 1 and 4, in a case where the display panel 10 includes the bridge structure 8, the third part 33 of the connecting lead 3 includes a portion 331 located on the second surface 1b, a portion 332 located on the selected second side surface 8cc and a portion 333 located on a side of the fourth surface 8b. The connecting lead 3 extends from the first surface, through the selected first side surface 1cc, to an edge of the second surface, and then, through the selected second side surface 8cc, extends to the fourth surface 8b. In this case, portions 333, located on the side of the fourth surface 8b, of third parts 33 of the plurality of connecting leads 3 are electrically connected to the plurality of back electrodes 4 in one-to-one correspondence.

The manufacturing process of the plurality of connecting leads 3 is that, for example: an entire connecting metal layer is formed on at least one selected first side surface 1cc of the substrate 1, for example, the connecting metal layer is formed through a three-dimensional sputtering coating process, and the formed connecting metal layer covers the first surface 1a of the substrate 1, the selected first side surface 1cc of the substrate 1, and a side of the second surface 1b of the substrate 1, in which a portion of the connecting metal layer located on a side of the second surface 1b of the substrate 1 covers the second surface 1b, the selected second side surface 8cc and the fourth surface 8b; then, the connecting metal layer is patterned by laser etching to form the independent plurality of connecting leads 3. Here, portions of the connecting metal layer respectively located on the first surface 1a of the substrate 1, located on the selected first side surface 1cc of the substrate 1 and located on the side of the second surface 1b of the substrate 1 form the first part 31, the second part 32, and the third part 33 of the connecting lead 3.

The light-emitting devices in the display panel 10 are, for example, Micro LEDs or Mini LEDs. Compared to traditional LEDs, the Micro LEDs or Mini LEDs have smaller particles, i.e., smaller volumes, therefore, in a case where the display area AA of the display panel 10 has a certain area, more and denser light-emitting devices can be installed in the display panel 10, making the connecting leads 3 of the display panel 10 denser. As a result, higher requirements are put forward for the precision and manufacturing speed of the manufacturing process of the connecting leads 3. However, the above manufacturing process of forming a connecting metal layer and patterning the connecting metal layer by laser etching is not conducive to the manufacture of the connecting leads 3 of the display panel 10 having the Micro LEDs or Mini LEDs, due to the low precision and low speed thereof.

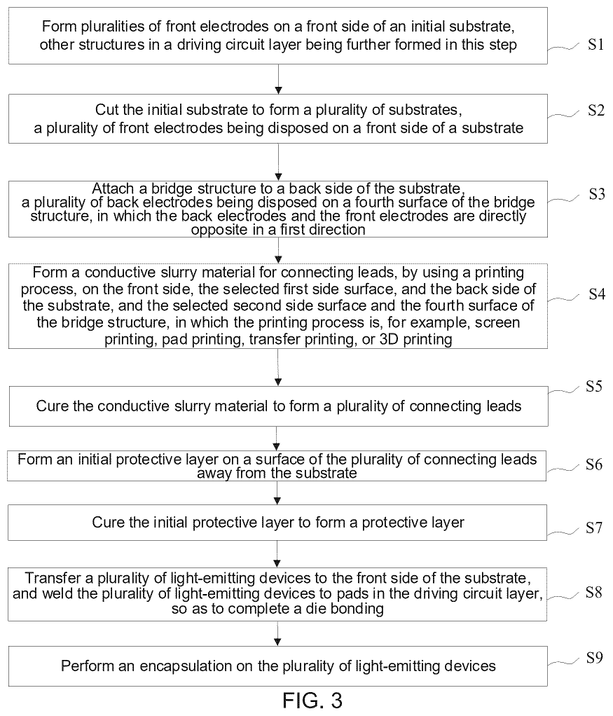

In order to achieve the high-precision and rapid manufacture of the connecting leads 3 of the display panel 10 having the Micros LED or Mini LED, in some embodiments, the connecting leads 3 are manufactured by using a printing process. In this case, as shown in FIG. 3, a manufacturing process of the display panel 10 includes the following steps (S1 to S9).

In S1, pluralities of front electrodes 2 are formed on a front side of an initial substrate. In this step, other structures in a driving circuit layer are further formed.

In S2, the initial substrate is cut to form a plurality of substrates 1, and a plurality of front electrodes 2 are disposed on a front side of a substrate 1.

In S3, a bridge structure 8 is attached to a back side of the substrate 1, and a plurality of back electrodes 4 are disposed on a fourth surface of the bridge structure 8, in which the back electrodes 4 and the front electrodes 2 are directly opposite in a first direction X.

In S4, a conductive slurry material for connecting leads is formed, by using a printing process, on the front side, the selected first side surface, and the back side of the substrate, and the selected second side surface and the fourth surface of the bridge structure, in which the printing process is, for example, screen printing, pad printing, transfer printing, or 3D printing.

In S5, the conductive slurry material is cured to form a plurality of connecting leads 3.

In S6, an initial protective layer is formed on a surface of the plurality of connecting leads 3 away from the substrate.

In S7, the initial protective layer is cured to form a protective layer 6.

In S8, a plurality of light-emitting devices are transferred to the front side of the substrate, and are welded to pads in the driving circuit layer, so as to complete a die bonding.

In S9, an encapsulation is performed on the plurality of light-emitting devices.

There are some problems in the manufacturing process of the display panel 10. In an aspect, in a case where the selected second side surface 8cc of the bridge structure 8 is a plane perpendicular to the third surface 8a, in the step S5, due to a step formed between the bridge structure 8 and the second surface 1b of the substrate 1, a segment difference from the second surface 1b directly to the fourth surface 8b is large, making it difficult for the conductive slurry material to climb upright on the selected second side surface 8cc, increasing the difficulty of the printing and reducing the distribution uniformity of the leveled conductive slurry material, and resulting in the formed connecting leads 3 being prone to breakage at a junction edge K of the selected second side surface 8cc and the fourth surface 8b (refer to the cracks in the connecting lead in FIG. 2), causing the product to have broken lines and to fail to display images. In another aspect, after the conductive slurry material for connecting leads is formed by printing, two curing processes are required to be performed: a curing of the conductive slurry material for connecting leads and a curing of the initial protective layer. Since the curing processes are mostly carried out under high temperature conditions, the material of the connecting leads 3 needs to be subjected to two high temperature processes, which is prone to deformation of the connecting leads 3 and further increases the possibility of breakage of the connecting leads 3 due to the stress at the junction edge K.

In light of this, as shown in FIGS. 4 and 5, some embodiments of the present disclosure provide a display panel 10, in which the third surface 8a and the fourth surface 8b of the bridge structure 8 have a first spacing L1. An intersection line of the selected second side surface 8cc and the fourth surface 8b is a first common edge H, and an intersection line of the selected second side surface 8cc and the third surface 8a is a second common edge N. An orthographic projection of the first common edge H on the third surface 8a and an orthographic projection of the second common edge N on the third surface 8a have a second spacing L2, and a ratio of the first spacing L1 to the second spacing L2 is in a range of 0.27 to 1.73. A distance between the second common edge N and the selected first side surface is a third spacing L3, and a value of the third spacing L3 is in a range of 0.5 mm to 2.0 mm.

It can be understood that the third surface 8a and the fourth surface 8b of the bridge structure 8 have a first spacing L1, and the first spacing L1 is a dimension of the bridge structure 8 along the first direction X, i.e., the thickness of the bridge structure 8. In a case where an orthographic projection of the first common edge H on the third surface 8a and an orthographic projection of the second common edge N on the third surface 8a have a second spacing L2, the second spacing L2 is a dimension of an orthographic projection of the selected second side surface 8cc on the third surface 8a along the third direction Z. That is to say, the selected second side surface 8cc is not a plane perpendicular to the third surface 8a, but a slope. By setting the ratio of the first spacing L1 to the second spacing L2 in a range of 0.27 to 1.73, an included angle between a plane where the first common edge H and the second common edge N are located and a plane where the third surface 8a is located is in a range of 15° to 60°. With such a setting, an inclination of the selected second side surface 8cc is limited, making a slope angle of the selected second side surface 8cc in a range of 15° to 60°. In this way, the conductive slurry material can slowly climb on the selected second side surface 8cc when the connecting leads 3 are manufactured through the printing process, which reduces the difficulty of printing and improves the uniformity of the leveled conductive slurry material, making the connecting leads 3 formed subsequently more reliable and avoiding the problem that the connecting leads 3 break at the junction edge K of the selected second side surface 8cc and the fourth surface 8b. Moreover, since the selected second side surface 8cc is a slope, portions of the connecting leads 3 formed on the selected second side surface 8cc are substantively conformal to the selected second side surface 8cc, that is, surfaces of the portions of the connecting leads 3 are also slopes. In this way, during the high temperature curing processes for initial connecting leads (i.e., the conductive slurry material) and the initial protective layer, the connecting leads 3 are not easily deformed and thus are not easily broken.

For example, the ratio of the first spacing L1 to the second spacing L2 may be 0.27, 0.50, 1, 1.50, or 1.73.

It can be understood that in a case where a distance between the second common edge N and the selected first side surface is a third spacing L3, the third spacing L3 is a distance between an edge of the selected second side surface 8cc proximate to the selected first side surface 1cc and the selected first side surface 1cc. By setting a value of the third spacing L3 in a range of 0.5 mm to 2.0 mm, a certain spacing exists between the selected second side surface 8cc and the selected first side surface 1cc in the third direction Z, so that the selected second side surface 8cc and the selected first side surface 1cc can avoid being directly connected, but are connected through a portion of the second surface 1b. In this way, in a case where the connecting lead 3 is manufactured through the printing process, a portion of the third part of the connecting lead is located on the second surface, and the remaining portions are located on the bridge structure, which increases the stability of the connecting leads and the substrate. Moreover, the connecting leads extend from the second surface, through the selected second side surface, to the fourth surface, which can prevent the conductive slurry material from continuously climbing on the selected first side surface 1cc and the selected second side surface 8cc. In this way, the conductive slurry material can slowly climb on the selected second side surface 8cc and the selected first side surface 1cc, reducing the difficulty of printing and enabling the conductive slurry material to be evenly distributed, thereby making the connecting leads 3 formed subsequently more reliable and reducing the risk of the breakage of the connecting leads 3. Moreover, since portions of the connecting leads 3 formed on the selected second side surface 8cc are substantively conformal to the selected second side surface 8cc, that is, surfaces of the portions of the connecting leads 3 are also slopes, the force on the connecting leads 3 is more uniform. In this way, during the high temperature curing process for the initial connecting leads and the high temperature curing process for the initial protective layer, the connecting leads 3 are not easily deformed.

For example, the third spacing L3 may be 0.5 mm, 1.0 mm, 1.5 mm, 1.8 mm, or 2.0 mm.

It will be noted that the third surface 8a and the fourth surface 8b may or may not be parallel. In a case where the third surface 8a and the fourth surface 8b are not parallel, the first spacing L1 is an average spacing between the third surface 8a and the fourth surface 8b. The orthographic projection of the first common edge H on the third surface 8a and the orthographic projection of the second common edge N on the third surface 8a may or may not be parallel. In a case where the orthographic projection of the first common edge H on the third surface 8a and the orthographic projection of the second common edge N on the third surface 8a are not parallel, the second spacing L2 is an average spacing between the orthographic projection of the first common edge H on the third surface 8a and the orthographic projection of the second common edge N on the third surface 8a. The second common edge N and the selected first side surface may or may not be parallel. In a case where the second common edge N and the selected first side surface are not parallel, the third spacing L3 is an average spacing between the second common edge N and the selected first side surface.

In some implementations, as shown in FIGS. 1 and 2, a dimension D7 of an end C of the portion of the connecting lead 3 located on the second surface 1b proximate to the bridge structure 8 in the second direction Y is greater than a dimension D8 of the remaining portions of the connecting lead 3 in the second direction Y. This is because the end C of the portion of the connecting lead 3 located on the second surface 1b proximate to the bridge structure 8 corresponds to a position before the conductive slurry material climbs along the selected second side surface 8cc. It can be understood that compared to a state in which the conductive slurry material is printed on a plane (e.g., the second plane), when being printed on a segment difference G of the selected second side surface 8cc, especially in a case where the selected second side surface 8cc is a plane, the conductive slurry material climbs the slope more difficultly, and the speed of movement will be reduced. This results in a certain accumulation of the conductive slurry material at the position before climbing, and this accumulation position corresponds to the end C of the portion of the connecting lead 3 located on the second surface 1b proximate to the bridge structure 8, which makes the dimension D7 of the end C of the portion of the connecting lead 3 located on the second surface 1b proximate to the bridge structure 8 in the second direction Y greater than the dimension D8 of the remaining portions of the connecting lead 3 in the second direction Y, causing dimensions of portions of the third part 33 of the connecting lead 3 in a direction perpendicular to an extension direction thereof to have a relatively low uniformity, and causing thicknesses of the portions of the third part 33 of the connecting lead 3 to also have a relatively low uniformity.

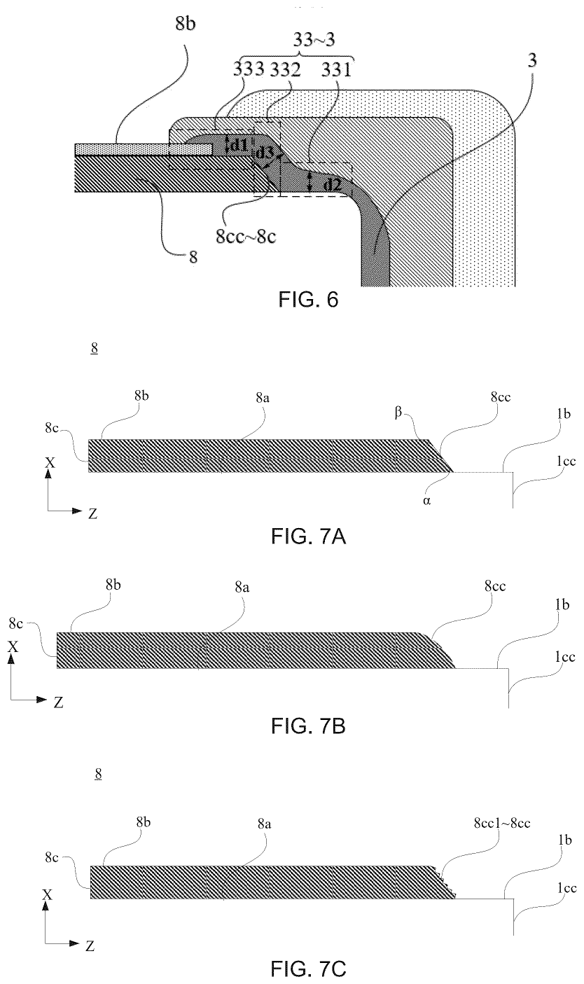

In some embodiments, as shown in FIG. 6, the portion of the connecting lead 3 located in a region corresponding to the fourth surface 8b has a first thickness d1, the portion of the connecting lead 3 located in a region corresponding to the second surface 1b has a second thickness d2, and the connecting lead 3 has a third thickness d3 at a position corresponding to the selected second side surface 8cc. Here, the first thickness d1 is greater than or equal to the second thickness d2, and a difference between the first thickness d1 and the second thickness d2 is in a range of 0 to 1 μm; and the third thickness d3 is greater than the first thickness d1 or the second thickness d2, and a difference between the third thickness d3 and the first thickness d1, or a difference between the third thickness d3 and the second thickness d2 is in a range of 1 μm to 3 μm.

In a case where the difference between the first thickness d1 and the second thickness d2 is in a range of 0 to 1 μm, a difference between a thickness of the portion 331 of the third part 33 of the connecting lead 3 located on the second surface 1b and a thickness of the portion 333 of the third part 33 of the connecting lead 3 located on a side of the fourth surface 8b is less than or equal to 1 μm, that is, a difference between thicknesses of the two portions is controlled within 1 μm. Correspondingly, the portion 331 of the third part 33 of the connecting lead 3 located on the second surface 1b is formed before the conductive slurry material climbs along the selected second side surface 8cc, and the portion 333 of the third part 33 of the connecting lead 3 located on a side of the fourth surface 8b is formed after the conductive slurry material climbs along the selected second side surface 8cc. Compared to a plane, since the selected second side surface 8cc is a slope, the conductive slurry material is less difficult to climb when being printed, the accumulation of the conductive slurry material at the position before climbing is reduced, and the thickness and dimension of the portion of the connecting lead at this position are both reduced. With such a setting, there is a small difference between the thickness of the portion of the connecting lead 3 corresponding to the position before the conductive slurry material climbs along the selected second side surface 8cc and the thickness of the portion of the connecting lead 3 corresponding to the position after the conductive slurry material finishes climbing along the selected second side surface 8cc.

In a case where the difference between the third thickness d3 and each of the first thickness d1 and the second thickness d2 is in a range of 1 μm to 3 μm, the difference between the thickness of the portion 331 of the third part 33 of the connecting lead 3 located on the second surface 1b and the thickness of the portion 332 of the third part 33 of the connecting lead 3 located on the selected second side surface 8cc, and the difference between the thickness of the portion 333 of the third part 33 of the connecting lead 3 located on a side of the fourth surface 8b and the thickness of the portion 332 of the third part 33 of the connecting lead 3 located on the selected second side surface 8cc are both less than or equal to 3 μm, so that for the portion 331 of the third part 33 of the connecting lead 3 located on the second surface 1b, the portion 332 of the third part 33 of the connecting lead 3 located on the selected second side surface 8cc, and the portion 333 of the third part 33 of the connecting lead 3 located on a side of the fourth surface 8b, the difference between thicknesses of any two is controlled within 3 μm. With such a setting, the difference between thicknesses of the portions of the third part 33 of the connecting lead 3 is small, so that the thickness uniformity of the entire third part 33 of the connecting lead 3 is improved, thereby reducing the difference between dimensions of the end of the portion of the connecting lead 3 located on the second surface 1b proximate to the bridge structure 8 and the remaining portions of the connecting lead 3, and reducing the risk of the breakage of the connecting leads 3.

For example, the first thickness d1 may be 2 μm, 2.5 μm, 2.7 μm, or 3 μm.

For example, the second thickness d2 may be 2 μm, 2.2 μm, 2.5 μm, or 3 μm.

For example, the third thickness d3 may be 3 μm, 3.7 μm, 4.0 μm, 4.5 μm, or 5 μm.

The third thickness d3 is greater than the first thickness d1 or the second thickness d2. This is because in a case where the connecting leads 3 is manufactured by a printing method, it is necessary to lift the printing pin at the position corresponding to the selected second side surface 8cc, so that the movement of the conductive slurry material is slowed down, making the conductive slurry material accumulate at this position. As a result, the connecting lead 3 has a high measured thickness at the position corresponding to the selected second side surface 8cc.

For example, the difference between the first thickness d1 and the second thickness d2 may be 0 μm, 0.1 μm, 0.5 μm, or 1 μm.

For example, the difference between the third thickness d3 and the first thickness d1 may be 1 μm, 1.5 μm, 2.0 μm, 2.5 μm, 2.7 μm, or 3.0 μm; and the difference between the third thickness d3 and the second thickness d2 may be 1 μm, 1.8 μm, 2.0 μm, 2.5 μm, or 3.0 μm.

It will be noted that the first thickness d1 is an average thickness of segments of the connecting lead 3 located in the region corresponding to the fourth surface 8b, that is, an average thickness of the portion 333 of the third part 33 of the connecting lead 3 located on a side of the fourth surface 8b. Moreover, a direction of the first thickness d1 is the first direction X, that is, a direction perpendicular to the fourth surface 8b. The second thickness d2 is an average thickness of segments of the connecting lead 3 located in the region corresponding to the second surface 1b, that is, an average thickness of the portion 331 of the third part 33 of the connecting lead 3 located on the second surface 1b. Moreover, a direction of the second thickness d2 is the first direction X, that is, the direction perpendicular to the second surface 1b. The third thickness d3 is an average thickness of segments of the connecting lead 3 at the position corresponding to the selected second side surface 8cc, that is, an average thickness of the portion 332 of the third part 33 of the connecting lead 3 located on the selected second side surface 8cc. Moreover, a direction of the third thickness d3 is a direction perpendicular to the selected second side surface 8cc.

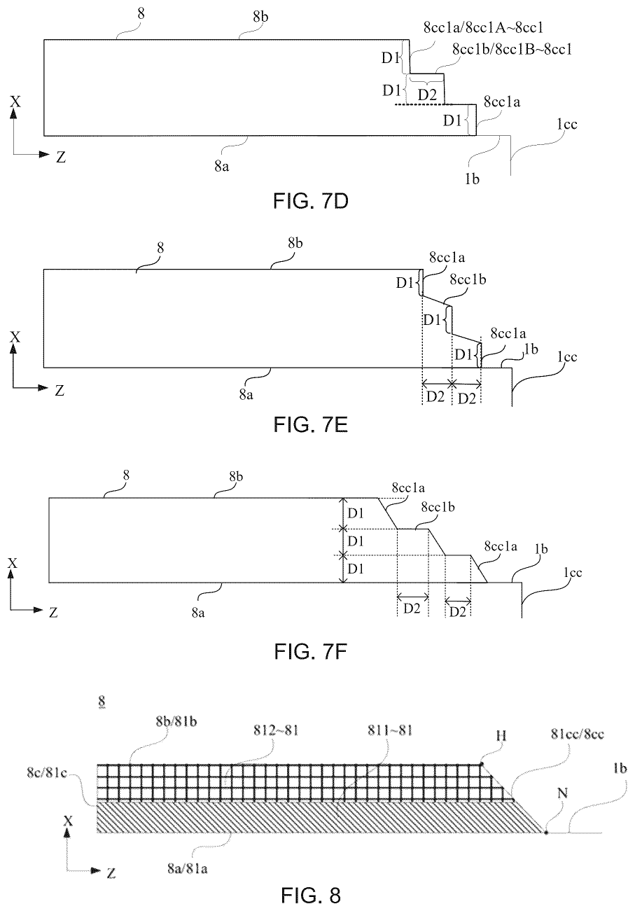

In some embodiments, as shown in FIGS. 7A to 7F, a section of the selected second side surface 8cc perpendicular to the first common edge H or the second common edge N is in a shape of a straight segment, a curved segment or a polyline segment, where the curved segment bends away from the second surface 1b.

As shown in FIG. 7A, in a case where the section of the selected second side surface 8cc perpendicular to the first common edge H or the second common edge N is in a shape of a straight segment, the selected second side surface 8cc is an inclined plane. Compared to a case where the selected second side surface 8cc is perpendicular to the third surface 8a, when the connecting leads 3 are manufactured on the inclined plane through the printing process, the uniformity of the leveled conductive slurry material is improved, and the formed connecting leads 3 are more reliable.

As shown in FIG. 7B, in a case where the section of the selected second side surface 8cc perpendicular to the first common edge H or the second common edge N is in a shape of a curved segment, the selected second side surface 8cc is an inclined curved surface. Compared to a case where the selected second side surface 8cc is perpendicular to the third surface 8a, when the connecting leads 3 are manufactured on the inclined curved surface through the printing process, the uniformity of the leveled conductive slurry material is improved, and the formed connecting leads 3 are more reliable. Moreover, the curved segment bents away from the second surface 1b, that is to say, the selected second side surface is an outwardly convex curved surface. By arranging the curved segment bent away from the second surface 1b, it can be avoided that the inclined curved surface forms a relatively upright slope at a position proximate to the fourth surface 8b, which in turn avoids the problem of the conductive slurry material having difficulty in climbing the slope in an upright position when printing the initial connecting leads.

It will be noted that in a case where the section of the selected second side surface 8cc perpendicular to the first common edge H or the second common edge N is in a shape of a curved segment, there may be one or more curved segments, which is not limited here. In a case where there are a plurality of curved segments, the plurality of curved segments are connected in sequence and are inclined as a whole.

As shown in FIGS. 7C to 7F, in a case where the section of the selected second side surface 8cc perpendicular to the first common edge H or the second common edge N is in a shape of a polyline segment, the selected second side surface 8cc is zigzag-like shaped as a whole. Compared to a case where the selected second side surface 8cc is perpendicular to the third surface 8a, when the connecting leads 3 are manufactured on the zigzag-like shaped surface through the printing process, the uniformity of the leveled conductive slurry material is improved, and the formed connecting leads 3 are more reliable.

In some embodiments, as shown in FIG. 7A, the selected second side surface 8cc is a plane, and an included angle between the selected second side surface 8cc and the third surface 8a is in a range of 10° to 80°.

In a case where the included angle α between the selected second side surface 8cc and the third surface 8a is in the range of 10° to 80°, an angle β between the selected second side surface 8cc and the fourth surface 8b is in a range of 100° to 170°. In this way, the conductive slurry material can be kept in a slowly climbing state on the selected second side surface 8cc when the connecting leads 3 are manufactured through the printing process.

By setting the included angle α between the selected second side surface 8cc and the third surface 8a less than or equal to 80°, the included angle α between the selected second side surface 8cc and the third surface 8a is not too large, to avoid forming a relatively upright slope, thereby avoiding the problem of the conductive slurry material being difficult to climb the slope in an upright position when printing the initial connecting leads. By setting the included angle α between the selected second side surface 8cc and the third surface 8a greater than or equal to 10°, the included angle α between the selected second side surface 8cc and the third surface 8a is not too small in favor of ensuring the third spacing L3.

For example, the included angle α between the selected second side surface 8cc and the third surface 8a may be 10°, 20°, 30°, 40°, 45°, 60° or 80°.

In some embodiments, as shown in FIG. 7D, the selected second side surface 8cc includes a plurality of sub-surfaces 8cc1 connected in sequence. In two adjacent sub-surfaces 8cc1, one sub-surface 8cc1 further away from the selected first side surface 1cc is further away from the second surface 1b than the other sub-surface 8cc1.

With such an arrangement, two adjacent sub-surfaces 8cc1 may be arranged along a direction from the second common edge N to the first common edge H, and an included angle between this arrangement direction and the third surface of the bridge structure 8 is less than 90°. In this way, the conductive slurry material can slowly climb on the selected second side surface 8cc when the connecting leads 3 are manufactured through the printing process, which reduces the difficulty of printing and improves the uniformity of the leveled conductive slurry material, making the connecting leads 3 formed subsequently more reliable and avoiding the problem that the connecting leads 3 break at the junction edge K of the selected second side surface 8cc and the fourth surface 8b (refer to the crack in the connecting lead in FIG. 2). Moreover, since portions of the connecting leads 3 formed on the selected second side surface 8cc are substantively conformal to the selected second side surface 8cc, that is, surfaces of the portions of the connecting leads 3 are also slopes. In this way, during the high temperature curing process for the initial connecting leads and the high temperature curing process for the initial protective layer, the connecting leads 3 are not easily deformed.

It will be noted that in two adjacent sub-surfaces 8cc1, one sub-surface 8cc1 further away from the selected first side surface 1cc is further away from the second surface 1b than the other sub-surface 8cc1, which means that in the two adjacent sub-surfaces 8cc1, a sub-surface 8cc1 further away from the selected first side surface 1cc and a sub-surface 8cc1 further away from the second surface 1b are the same sub-surface 8cc1. The following takes a sub-surface 8cc1A and a sub-surface 8cc1B of the selected second side surface 8cc as an example for detailed description. As shown in FIG. 7D, for the sub-surface 8cc1A and the sub-surface 8cc1B of the selected second side surface 8cc, the sub-surface 8cc1A is a sub-surface 8cc1 that is further away from the selected first side surface 1cc and further away from the sub-surface 8cc1 of second surface 1b.

For example, the plurality of sub-surfaces 8cc1 are all curved surfaces, or the plurality of sub-surfaces 8cc1 are all planes, or some of the plurality of sub-surfaces 8cc1 are curved surfaces, and the remaining sub-surfaces 8cc1 are planes. In a case where some of the plurality of sub-surfaces 8cc1 are curved surfaces and the remaining sub-surfaces 8cc1 are planes, there is no restriction on the arrangement of the planar sub-surfaces 8cc1 and the curved sub-surfaces 8cc1.

In some embodiments, as shown in FIGS. 7D to 7F, the plurality of sub-surfaces 8cc1 are planes, and the selected second side surface 8cc is in a stepped shape. The selected second side surface 8cc includes at least two first sub-surfaces 8cc1a and at least one second sub-surface 8cc1b that are alternately arranged, in which in the plurality of sub-surfaces 8cc1, a sub-surface 8cc1 closest to the fourth surface 8b and a closest to the second surface 1b are both first sub-surfaces 8cc1a. The at least two first sub-surfaces 8cc1a are parallel to the selected first side surface 1cc; and/or the at least one second sub-surface 8cc1b are parallel to the second surface 1b.

Taking directions shown in FIGS. 7D to 7F as an example, in a case where the plurality of sub-surfaces 8cc1 are planes and the selected second side surface 8cc is in a stepped shape, the selected second side surface 8cc includes at least two connecting surfaces and at least one step surface, in which the first sub-surface 8cc1a is a connecting surface, and the second sub-surface 8cc1b is a step surface. In the plurality of sub-surfaces 8cc1, a sub-surface adjacent to the fourth surface 8b or the second surface 1b is a first sub-surfaces 8cc1a. As shown in FIGS. 7D and 7E, in a case where the at least two first sub-surfaces 8cc1a are parallel to the selected first side surface 1cc, connecting surfaces are perpendicular to the third surface 8a; and the second sub-surface 8cc1b is not limited, which may or may not be parallel to the second surface 1b. As shown in FIGS. 7D and 7F, in a case where the second sub-surface 8cc1b is parallel to the second surface 1b, step surfaces are parallel to the third surface 8a; and the first sub-surfaces 8cc1a are not limited, which may or may not be parallel to the selected first side surface 1cc.

By setting the selected second side surface 8cc in a stepped shape, compared to a case where the selected second side surface 8cc is a plane perpendicular to the third surface 8a, when the connecting leads 3 are manufactured through the printing process, a state of the conductive slurry material on the selected second side surface 8cc changes from an upright climbing to a segmented climbing, which reduces the difficulty of printing and improves the uniformity of the leveled conductive slurry material, making the connecting leads 3 formed subsequently more reliable and avoiding the problem that the connecting leads 3 break at the junction edge K of the selected second side surface 8cc and the fourth surface 8b. Moreover, since portions of the connecting leads 3 formed on the selected second side surface 8cc are substantively conformal to the selected second side surface 8cc, that is, surfaces of the portions of the connecting leads 3 are also slopes. In this way, during the high temperature curing process for the initial connecting leads and the high temperature curing process for the initial protective layer, the connecting leads 3 are not easily deformed.

In some embodiments, as shown in FIGS. 7D to 7F, a dimension of an orthographic projection of each of the at least two first sub-surfaces 8cc1a on a first reference plane in the first direction X is a first dimension D1, where the first reference plane is parallel to the selected first side surface 1cc, and the first direction X is a thickness direction of the substrate 1.

With such an arrangement, the selected second side surface 8cc has a plurality of connecting surfaces with equal height, and the segment distance of the first spacing L1 is divided into a plurality of relatively small segments in the first direction X. In this way, the uniformity of the leveled conductive slurry material on the selected second side surface 8cc is improved when the connecting leads 3 are manufactured through the printing process, which reduces the difficulty of printing and improves the uniformity of the leveled conductive slurry material.

In some embodiments, as shown in FIGS. 7D to 7F, a dimension of an orthographic projection of the at least one second sub-surface 8cc1b on a second reference plane in the third direction Z is a second dimension D2, where the second reference plane is parallel to the second surface 1b, and the third direction Z is perpendicular to the selected first side surface 1cc.

With such an arrangement, orthographic projections of two adjacent second sub-surfaces 8cc1b of the selected second side surface 8cc on the third surface 8a do not overlap with each other, and orthographic projections thereof on the plane parallel to the selected first side surface 1cc are arranged at equal interval, that is, the second spacing L2 is divided into a plurality of segments with the same dimension in the third direction Z. In this way, the uniformity of the leveled conductive slurry material on the selected second side surface 8cc is improved when the connecting leads 3 are manufactured through the printing process.

In some other embodiments, as shown in FIG. 7D, a dimension of an orthographic projection of each of the at least two first sub-surfaces 8cc1a on the first reference plane in the first direction X is a first dimension D1, and a dimension of an orthographic projection of the at least one second sub-surface 8cc1b on the second reference plane in the third direction Z is a second dimension D2. Moreover, the first dimension D1 is equal to the second dimension D2.

With such an arrangement, each step surface of the selected second side surface 8cc has the same dimension, and each connecting surface of the selected second side surface 8cc has the same dimension. The segment distance of the first spacing L1 is divided into a plurality of relatively small segments in the first direction X, and the second spacing L2 is divided into a plurality of uniform segments in the third direction Z. In this way, the uniformity of the leveled conductive slurry material on the selected second side surface 8cc is improved when the connecting leads 3 are manufactured through the printing process.

The following describes the composition of the bridge structure and the specific implementation of the selected second side surface in a shape of a slope.

In some embodiments, as shown in FIG. 8, the bridge structure 8 includes a circuit board 81, and the circuit board 81 includes a fifth surface 81a and a sixth surface 81b arranged oppositely, and a plurality of third side surface 81c connecting the fifth surface 81a and the sixth surface 81b. The plurality of third side surfaces 81c include at least one selected third side surface 81cc, where the selected third side surface 81cc serves as the selected second side surface 8cc. The plurality of back electrodes 4 are arranged side by side at intervals on the sixth surface 81b.

In a case where the bridge structure 8 includes the circuit board 81, the fifth surface 81a of the circuit board 81 serves as the third surface 8a of the bridge structure 8, and the sixth surface 81b of the circuit board 81 serves as the fourth surface 8b of the bridge structure 8. In this case, the circuit board 81 may serve as a carrier for the plurality of back electrodes 4.

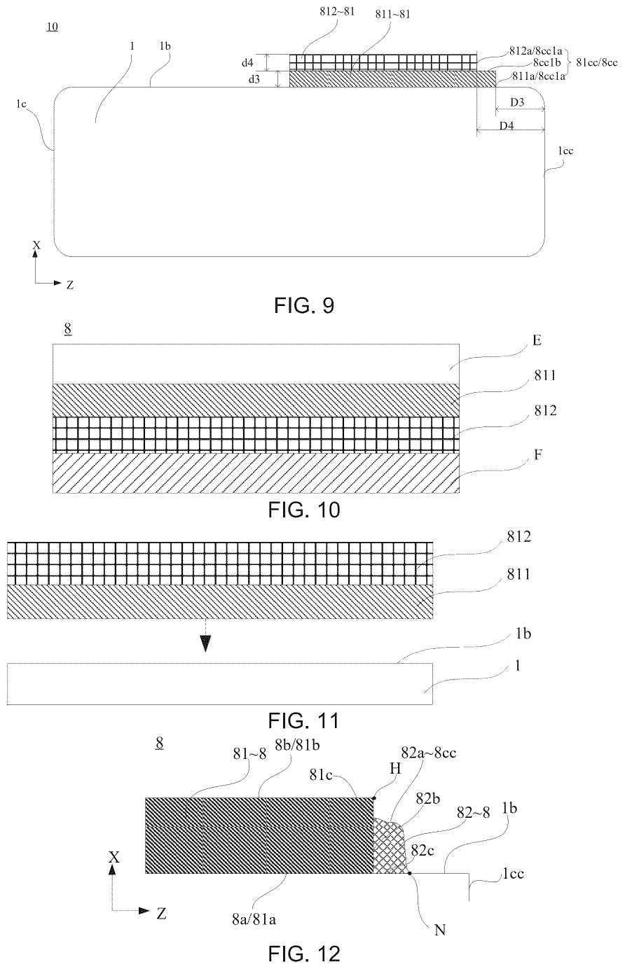

In some embodiments, as shown in FIGS. 8 and 9, the circuit board 81 includes an adhesive layer 811 and a carrier board body 812 disposed in stack. The adhesive layer 811 is closer to the substrate 1 than the carrier board body 812. As shown in FIG. 8, the adhesive layer 811 and the carrier board body 812 are cut, so that surfaces of the adhesive layer 811 and the carrier board body 812 proximate to the selected first side surface are slopes, that is, the selected third side surface 81cc of the circuit board 81 is a slope, thereby realizing that the first common edge H of the selected third side surface 81cc of the circuit board 81 is further away from the selected first side surface 1cc than the second common edge N, and orthographic projections of the two common edges on the second surface of the substrate have the second spacing therebetween.

As shown in FIG. 9, the selected third side surface 81cc of the circuit board 81 is in a stepped shape, and a distance D4 between an end of the carrier board body 812 proximate to the selected first side surface 1cc and the selected first side surface 1cc is greater than a distance D3 between an end of the adhesive layer 811 proximate to the selected first side surface 1cc and the selected first side surface 1cc.

The carrier board body 812 is a portion of the circuit board 81 that serves as a carrier for the plurality of back electrodes 4, and the adhesive layer 811 is used to connect the carrier board body 812 to the substrate. It can be understood that the adhesive layer 811 is closer to the substrate 1 than the carrier board body 812, so that the adhesive layer 811 can realize the function of connecting the carrier board body 812 to the substrate. By setting the distance D4 between the end of the carrier board body 812 proximate to the selected first side surface 1cc and the selected first side surface 1cc greater than the distance D3 between the end of the adhesive layer 811 proximate to the selected first side surface 1cc and the selected first side surface 1cc, the selected third side surface 81cc of the circuit board 81 can form a step, which can satisfy the condition that the ratio of the first spacing L1 to the second spacing L2 is in a range of 0.27 to 1.73. In this way, when the connecting leads 3 are manufactured through the printing process, the conductive slurry material can slowly climb on the selected third side surface 81cc, which reduces the difficulty of printing and makes the conductive slurry material more evenly distributed.

For example, as shown in FIG. 9, in a case where the selected third side surface 81cc of the circuit board 81 is in a stepped shape, there may be two first sub-surfaces 8cc1, in which an end surface 811a of the adhesive layer 811 proximate to the selected first side surface 1cc serves as a first sub-surface 8cc1a proximate to the substrate 1, and an end surface 812a of the carrier board body 812 proximate to the selected first side surface 1cc serves as a first sub-surface 8cc1a away from the substrate 1. The end surface 811a of the adhesive layer 811 proximate to the selected first side surface 1cc, the end surface 812a of the carrier board body 812 proximate to the selected first side surface 1cc, and a second sub-surface 8cc1b located therebetween together form the selected second side surface 8cc.

With such an arrangement, the carrier board body 812 and the adhesive layer 811 can be cut separately, and a cutting line of the adhesive layer 811 is closer to the selected first side surface 1cc than a cutting line of the carrier board body 812, thereby forming the stepped shaped selected third side surface 81cc, simplifying the method of forming the selected third side surface 81cc of the circuit board 81.

For example, the carrier board body is made of a material of polyimide. The polyimide material has the characteristics of high precision, high temperature resistance, and low expansion and contraction, so that the carrier board body is not prone to displacement during the subsequent high temperature processes (such as reflow soldering).

In some embodiments, as shown in FIG. 9, a thickness d3 of the adhesive layer 811 is greater than a thickness d4 of the carrier board body 812.

With such a setting, the connection firmness between the carrier board body and the substrate 1 may be increased, preventing the carrier board body 812 from moving during the subsequent processes of the display panel 10 and thus affecting the position accuracy of the back electrodes 4.

In some embodiments, as shown in FIG. 9, a ratio of the thickness d3 of the adhesive layer 811 to the thickness d4 of the carrier board body 812 is in a range of 1.4 to 1.6.

It can be understood that in a case where a difference between the thickness d3 of the adhesive layer 811 and the thickness d4 of the carrier board body 812 is too large, the thickness of the thicker one of the adhesive layer 811 and the carrier board body 812 is proximate to the thickness of the circuit board 81. In this way, even if the stepped shape selected second side surface 8cc is formed, the segment difference of the selected second side surface 8cc is still large, and it is impossible to achieve the purpose of the conductive slurry material slowly climbing on the selected second side surface 8cc. By setting the ratio of the thickness d3 of the adhesive layer 811 to the thickness d4 of the carrier board body 812 in a range of 1.4 to 1.6, the difference between the thickness d3 of the adhesive layer 811 and the thickness d4 of the carrier board body 812 will not be too large, the stepped shape selected second side surface 8cc can be formed. Compared to a case where the selected second side surface 8cc is a plane perpendicular to the third surface 8a, the uniformity of the leveled conductive slurry material is improved when the connecting leads 3 are manufactured through the printing process, which makes the connecting leads 3 formed more reliable, reducing the difficulty of printing and improving the uniformity of the leveled conductive slurry material. For example, the ratio of the thickness d3 of the adhesive layer 811 to the thickness d4 of the carrier board body 812 may be 1.4, 1.5, or 1.6.

In order to increase the feasibility of attaching the circuit board 81 to the second surface 1b of the substrate 1 with high precision, in some examples, as shown in FIGS. 10 and 11, before the circuit board 81 is attached to the second surface 1b of the substrate 1, a release film E is provided on a surface of the adhesive layer 811 away from the carrier board body 812, and a reinforcing film F is provided on a surface of the carrier board body 812 away from the adhesive layer 811. The release film E can prevent the adhesive layer 811 from adhering to other foreign objects and affecting the adhesive performance before attaching the circuit board 81. The reinforcing film F can increase the strength of the carrier board body 812, and prevent the carrier board body from curling or bending during the attachment process of the circuit board 81, and thus affecting the attachment. It will be noted that the release film E needs to be removed before the circuit board 81 is attached, and the reinforcing film F needs to be removed after the circuit board 81 is attached.

The above embodiments are for making improvements to the structure of the circuit board 81 itself to form the inclined selected second side surface of the bridge structure, and another implementation is described below.

In some embodiments, as shown in FIG. 12, the bridge structure 8 includes: a circuit board 81 and a buffer structure 82. The circuit board 81 includes a fifth surface 81a and a sixth surface 81b arranged oppositely, and a plurality of third side surfaces 81c connecting the fifth surface 81a and the sixth surface 81b. The plurality of back electrodes 4 are arranged side by side at intervals on the sixth surface 81b. The buffer structure 82 is located on a side of the circuit board 81 proximate to the selected first side surface 1cc. An outer surface 82a of the buffer structure serves as at least a portion of the selected second side surface 8cc, and the outer surface 82a of the buffer structure is a surface of the buffer structure 82 away from the circuit board 81 and the second surface 1b.

It will be noted that the outer surface 82a of the buffer structure is the surface of the buffer structure 82 away from the circuit board 81 and the second surface 1b, which means that, shown in FIG. 12, the surface of the buffer structure 82 can be divided into three portions: the first portion is a first inner surface 82b of the buffer structure 82 that is in contact with the circuit board 81, the second portion is a second inner surface 82c of the buffer structure 82 that is in contact with the second surface 1b of the substrate 1, and the third portion is the outer surface 82a of the buffer structure.

The buffer structure 82 is located on the side of the circuit board 81 proximate to the selected first side surface 1cc. By arranging the buffer structure 82 on the side of the circuit board proximate to the selected first side surface 1cc, the outer surface 82a of the buffer structure serves as at least a portion of the selected second side surface 8cc, so that a boundary edge between the outer surface 82a of the buffer structure and the second inner surface 82c serves as the second common edge N, and a boundary edge between the sixth surface 81b of the circuit board 81 and the selected third side surface 81cc serves as the first common edge H. Compared to a case without the buffer structure 82, such an arrangement enables the second common edge N to be further away from the first common edge H, which is beneficial to forming the second spacing L2 between the second common edge N and the first common edge H, making the selected second side surface 8cc a slope, thereby improving the uniformity of the leveled conductive slurry material when the connecting leads 3 are manufactured through the printing process, and making the formed connecting leads 3 more reliable.

Since the outer surface 82a of the buffer structure serves as at least a portion of the selected second side surface 8cc, the conductive slurry material can slowly climb on the outer surface 82a of the buffer structure when the connecting leads 3 are manufactured through the printing process.

The bridge structure 8 includes the circuit board 81 and the buffer structure 82. The outer surface 82a of the buffer structure serves as at least a portion of the selected second side surface 8cc, including at least the four situations as follows.

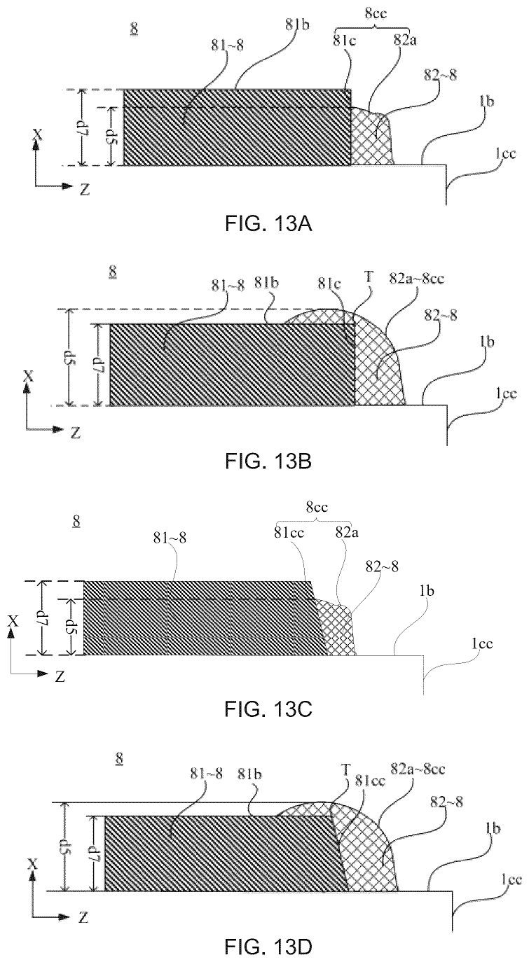

First situation: as shown in FIGS. 12 and 13A, a side surface of the circuit board 81 proximate to the selected first side surface 1cc is a plane perpendicular to the third surface 8a. The buffer structure 82 is located on the side of the circuit board 81 proximate to the selected first side surface 1cc, and a dimension d5 of the buffer structure 82 along the first direction X is less than a thickness d7 of the circuit board 81. In this case, the side surface 81c of the circuit board 81 proximate to the selected first side surface 1cc and the outer surface 82a of the buffer structure together form the selected second side surface 8cc. By providing the buffer structure 82, the inclination of a portion of the selected second side surface 8cc proximate to the second surface 1b of the substrate 1 becomes small.

Second situation: as shown in FIGS. 12 and 13B, a side surface of the circuit board 81 proximate to the selected first side surface 1cc is a plane perpendicular to the third surface 8a. The buffer structure 82 is located on the side of the circuit board 81 proximate to the selected first side surface 1cc, and a dimension d5 of the buffer structure 82 along the first direction X is greater than or equal to a thickness d7 of the circuit board 81. In this case, the outer surface 82a of the buffer structure is the selected second side surface 8cc. By providing the buffer structure 82, the inclination of the entire selected second side surface 8cc proximate to the second surface 1b of the substrate 1 becomes small.

Third situation: as shown in FIGS. 12 and 13C, the circuit board 81 includes a fifth surface 81a and a sixth surface 81b arranged oppositely, and a plurality of third side surfaces 81c connecting the fifth surface 81a and the sixth surface 81b, and the plurality of third side surfaces 81c include at least one selected third side surface 81cc. A section of the selected third side surface 81cc perpendicular to the first common edge H or the second common edge N is in a shape of a straight segment, a curved segment or a polyline segment, where the curved segment is bent away from the second surface 1b; or the selected third side surface 81cc includes a plurality of sub-surfaces 8cc1 connected in sequence. The buffer structure 82 is located on a side of the circuit board 81 proximate to the selected first side surface 1cc. Furthermore, a dimension d5 of the buffer structure 82 along the first direction X is less than a thickness d7 of the circuit board 81. In this case, the selected third side surface 81cc and the outer surface 82a of the buffer structure together form the selected second side surface 8cc, and the inclination of the entire selected second side surface 8cc becomes small, in which by providing the selected third side surface 81cc, the inclination of a portion of the selected second side surface 8cc away from the second surface 1b of the substrate 1 becomes small, and by providing the buffer structure 82, the inclination of a portion of the selected second side surface 8cc proximate to the second surface 1b of the substrate 1 becomes small.

Fourth situation: as shown in FIGS. 12 and 13D, the circuit board 81 includes a fifth surface 81a and a sixth surface 81b arranged oppositely, and a plurality of third side surfaces 81c connecting the fifth surface 81a and the sixth surface 81b, and the plurality of third side surfaces 81c include at least one selected third side surface 81cc. A section of the selected third side surface 81cc perpendicular to the first common edge H or the second common edge N is in a shape of a straight segment, a curved segment or a polyline segment, where the curved segment is bent away from the second surface 1b; or the selected third side surface 81cc includes a plurality of sub-surfaces 8cc1 connected in sequence. The buffer structure 82 is located on a side of the circuit board 81 proximate to the selected first side surface 1cc. Furthermore, a dimension d5 of the buffer structure 82 along the first direction X is greater than or equal to a thickness d7 of the circuit board 81. In this case, the outer surface 82a of the buffer structure is the selected second side surface 8cc. In this way, by providing the selected third side surface 81cc, the inclination of the selected second side surface 8cc becomes small, and by providing the buffer structure 82, the inclination of the selected second side surface 8cc further becomes small. Here, the third situation and the fourth situation are the implementations in which the improvement of the structure of the circuit board itself and the provision of the buffer structure are combined.

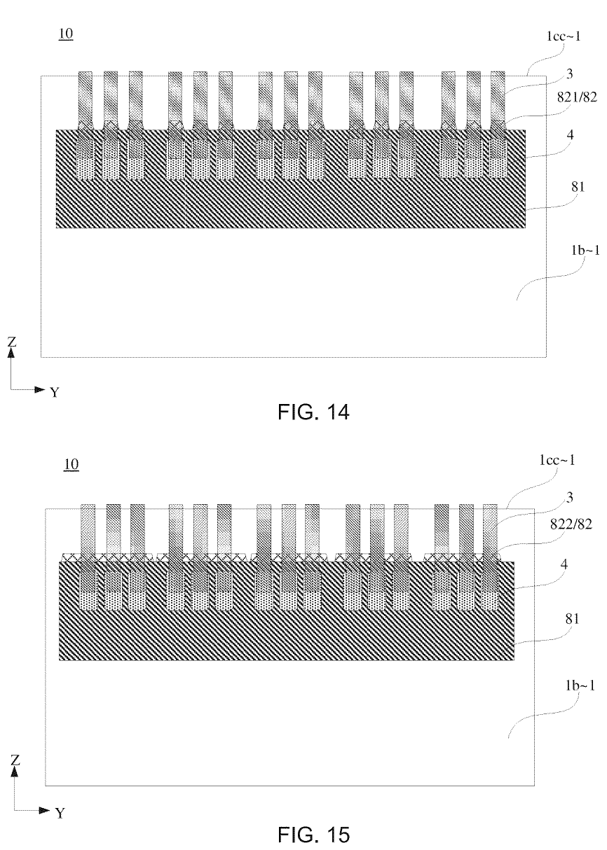

In some embodiments, as shown in FIG. 14, the buffer structure 82 includes a plurality of first buffer sub-structures 821, and at least a portion of each connecting lead 3 is disposed on a corresponding first buffer sub-structure 821 of the plurality of first buffer sub-structures 821.

In this case, the number of the plurality of first buffer sub-structures 821 is consistent with the number of the plurality of connecting leads 3, and the plurality of first buffer sub-structures 821 are arranged along the second direction Y, which means that a plurality of arc island-shaped buffer blocks are formed on the side surface of the circuit board 81. In this way, when the connecting leads 3 are manufactured through the printing process, the conductive slurry material forming each connecting lead 3 can slowly climb along an outer surface of the first buffer sub-structure 821 corresponding thereto. It will be noted that for the description of the outer surface of the first buffer sub-structure 821, please refer to the above description of the outer surface 82a of the buffer structure, and no further description will be given.

In some embodiments, as shown in FIG. 15, the plurality of connecting leads 3 include multiple groups of connecting leads 3, and each group of connecting leads 3 includes at least two connecting leads 3; and the buffer structure 82 includes a plurality of second buffer sub-structures 822, and at least a portion of each group of connecting leads 3 is disposed on a corresponding second buffer sub-structure 822 of the plurality of second buffer sub-structures 822.

In this case, the number of the plurality of second buffer sub-structures 822 is consistent with the number of the multiple groups of connecting leads 3, and the plurality of second buffer sub-structures 822 are arranged along the second direction Y, which means that a plurality of group-shaped buffer blocks are formed on the side surface of the circuit board 81. In this way, when the connecting leads 3 are manufactured through the printing process, the conductive slurry material forming each group of connecting leads 3 can slowly climb along an outer surface of the second buffer sub-structure 822 corresponding thereto. It will be noted that for the description of the outer surface of the second buffer sub-structure 822, please refer to the above description of the outer surface 82a of the buffer structure, and no further description will be given.

For example, as shown in FIG. 15, each group of connecting leads 3 includes three connecting leads 3.

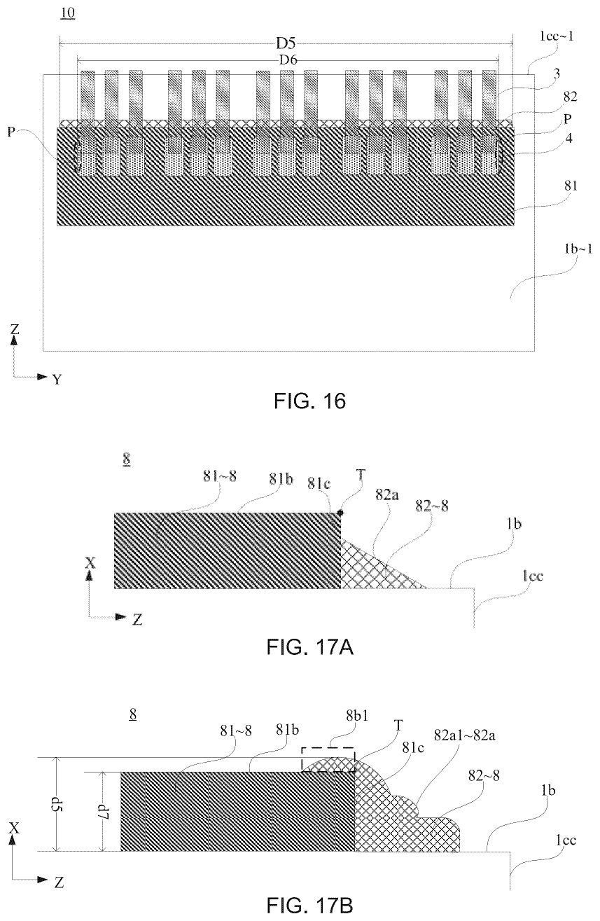

In some embodiments, as shown in FIG. 16, the buffer structure 82 extends along a second direction Y, the second direction Y being an extension direction of a boundary line between the selected first side surface 1cc and the second surface 1b; and a length D5 of the buffer structure 82 is greater than a distance D6 between outer side edges P of two connecting leads 3 of the plurality of connecting leads 3 whose orthographic projections on the second surface 1b are located outermost, the outer side edges P of the two connecting leads 3 being side edges of the two connecting leads 3 away from each other.

Such an arrangement means that a whole strip of buffer layer is formed on the side surface of the circuit board 81, so that a side of each connecting lead 3 away from the selected first side surface 1cc is provided thereon with a portion of the buffer structure 82 while simplifying the manufacturing process of the buffer structure 82. In this way, when the connecting leads 3 are manufactured through the printing process, each connecting lead 3 can slowly climb along a portion of the outer surface 82a of the buffer structure.

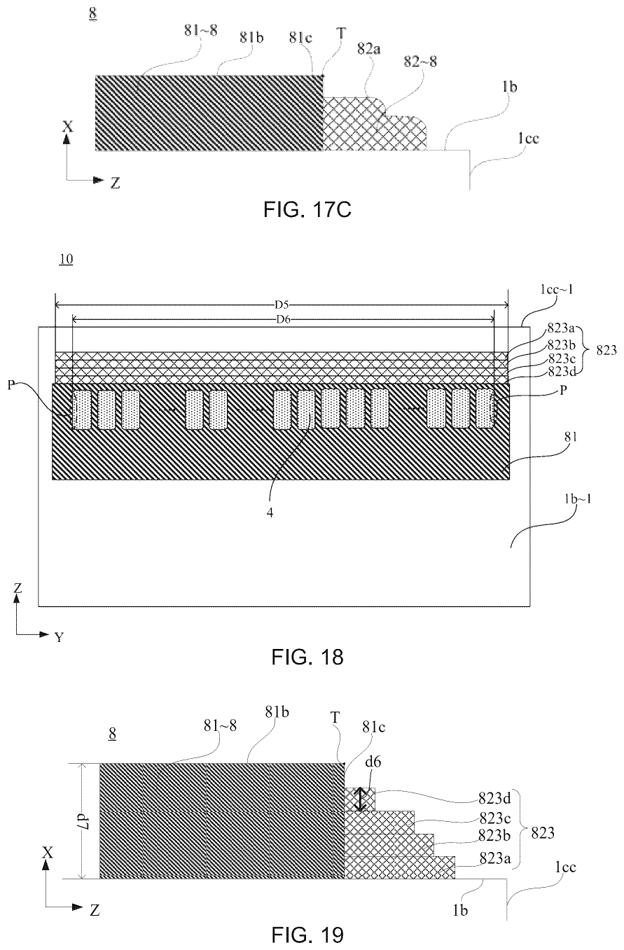

In some embodiments, as shown in FIGS. 17A to 17C, a section, perpendicular to the first common edge H or the second common edge N, of a surface of the buffer structure 82 away from the circuit board 81 and the second surface 1b is in a shape of a straight segment, a curved segment or a polyline segment, where the curved segment is bent away from the second surface 1b; or the surface of the buffer structure 82 away from the circuit board 81 and the second surface 1b includes a plurality of sub-surfaces 82a1 connected in sequence.

The surface of the buffer structure 82 away from the circuit board 81 and the second surface 1b is the outer surface 82a of the buffer structure. In a case where the outer surface 82a of the buffer structure serves as at least a portion of the selected second side surface 8cc, through the above arrangement, the inclination of the outer surface 82a of the buffer structure becomes small, that is, the inclination of at least a portion of the selected second side surface 8cc becomes small. When the connecting leads 3 are manufactured through the printing process, the conductive slurry material slowly climbs on the outer surface 82a of the buffer structure.

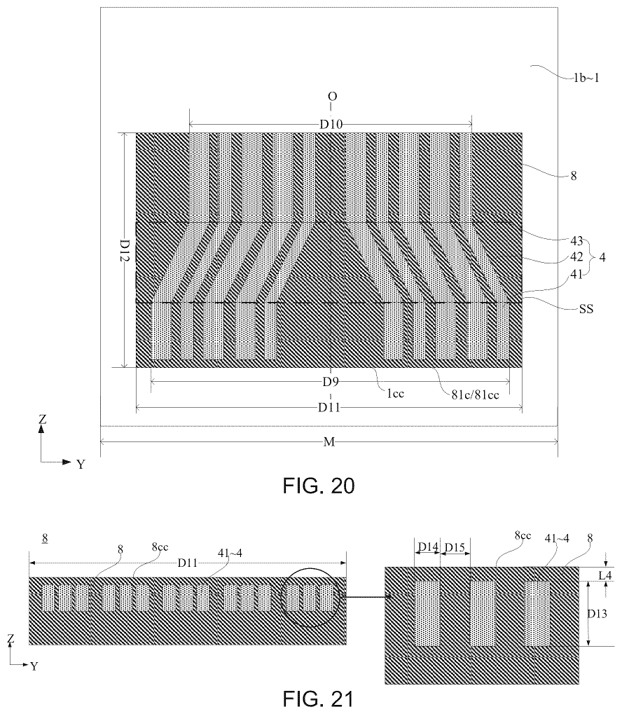

In some embodiments, as shown in FIGS. 18 and 19, the buffer structure 82 extends along a second direction Y, the second direction Y being an extension direction of a boundary line between the selected first side surface 1cc and the second surface 1b; and a length D5 of the buffer structure 82 is greater than a distance D6 between outer side edges P of two connecting leads 3 of the plurality of connecting leads 3 whose orthographic projections on the second surface 1b are located outermost, the outer side edges P of the two connecting leads 3 being side edges of the two connecting leads 3 away from each other. Furthermore, the buffer structure 82 includes a plurality of third buffer sub-structures 823 arranged along the first direction X and with the same dimension along the second direction Y. The plurality of third buffer sub-structures 823 make the outer surface 82a of the buffer structure have a stepped shape.

With such an arrangement, the segment difference on the outer surface 82a of the buffer structure is reduced, and the segment distance of the first spacing L1 is divided into a plurality of relatively small segments in the first direction X, while the second spacing L2 is divided into a plurality of segments in the third direction Z. In this way, when the connecting leads 3 are manufactured through the printing process, the uniformity of the leveled conductive slurry material on the selected second side surface 8cc is improved; moreover, the buffer structure 82 has a strip structure as a whole, and the manufacturing process is simple.

For example, as shown in FIGS. 18 and 19, the number of the plurality of third buffer sub-structures 823 is four, which are a third buffer sub-structure 823a, a third buffer sub-structure 823b, a third buffer sub-structure 823c, and a third buffer sub-structure 823d. As shown in FIG. 19, the thickness d7 of the circuit board 81 in the first direction X is 0.1 mm, the thicknesses of the plurality of third buffer sub-structures 823 in the first direction X are equal, for example, the thickness d6 of each third buffer sub-structure 823 in the first direction X is 20 μm. With such a setting, the segment differences between adjacent step surfaces of the outer surface 82a of the buffer structure are more consistent. When the connecting leads 3 are manufactured through the printing process, the uniformity of the leveled conductive slurry material on the selected second side surface 8cc is improved, and the connecting leads 3 subsequently formed will not be broken due to the large segment difference.

In some embodiments, as shown in FIGS. 13B, 13D and 17B, there is a junction T of a side surface 81c of the circuit board 81 proximate to the selected first side surface 1cc and the sixth surface 81b of the circuit board 81.

Since the intersection line between the side surface 81c of the circuit board 81 proximate to the selected first side surface 1cc and the sixth surface 81b of the circuit board 81 is relatively sharp, the conductive slurry material is subject to greater force at this location, during the high temperature curing process for the initial connecting leads and the high temperature curing process for the initial protective layer, deformation easily occurs, which increases the possibility of the breakage of the connecting leads 3. In light of this, by arranging the buffer structure 82 to cover the junction T of the side surface 81c of the circuit board 81 proximate to the selected first side surface 1cc and the sixth surface 81b of the circuit board 81, when the connecting leads 3 are manufactured through a printing process, the conductive slurry material forming the connecting leads 3 can bypass the intersection line between the side surface 81c of the circuit board 81 proximate to the selected first side surface 1cc and the sixth surface 81b of the circuit board 81 to reach the sixth surface 81b and connect the back electrodes 4, thereby achieving a smooth transition, which reduces the risk of the conductive slurry material breaking at the intersection line of the side surface 81c of the circuit board 81 proximate to the selected first side surface 1cc and the sixth surface 81b of the circuit board 81.

It can be understood that in a case where the buffer structure 82 covers the junction T of the side surface 81c of the circuit board 81 proximate to the selected first side surface 1cc and the sixth surface 81b of the circuit board 81, the dimension d5 of the buffer structure 82 in the first direction X is greater than or equal to the thickness d7 of the circuit board 81, corresponding to the second situation and the fourth situation.

It will be noted that in a case where the buffer structure 82 covers the junction T of the side surface 81c of the circuit board 81 proximate to the selected first side surface 1 cc and the sixth surface 81b of the circuit board 81, in the outer surface 82a of the buffer structure, a portion 8b1 located on a side of the fourth surface 8b (i.e., the portion corresponding to the dotted rectangular frame in FIG. 17B) forms a portion of the fourth surface 8b.

In some embodiments, a material of the buffer structure 82 includes an organic material.

For example, the material of the buffer structure 82 may be resin or polyimide.

The organic material is not easily deformed at the high temperature. When the connecting leads 3 are manufactured through the printing process, the buffer structure 82, which is formed by using the organic material, is not easily deformed during the high temperature curing process for the initial connecting leads and the high temperature curing process for the initial protective layer, which can enable the conductive slurry material to climb along the buffer structure 82 slowly and steadily.

In some embodiments, as shown in FIG. 20, each back electrode 4 includes a first straight part 41, a diagonal part 42, and a second straight part 43. The first straight part 41 extends in a direction perpendicular to the second direction Y, where the second direction Y is an extension direction of a boundary line between the selected first side surface and the second surface 1b. The diagonal part 42 is connected to the first straight part 41, and the extension direction of the first straight part 41 intersects an extension direction of the diagonal part 42. The second straight part 43 is connected to the diagonal part 42 and extends in the direction perpendicular to the second direction Y. The second straight part 43 is further away from the selected first side surface 1cc than the first straight part 41. The third part 33 of the connecting lead 3 is electrically connected to the first straight part 41, and the second straight part 43 is used to connect the flexible circuit board 9. First straight parts 41 of the plurality of back electrodes 4 are arranged along the second direction Y, second straight parts 43 of the plurality of back electrodes 4 are arranged along the second direction Y, and a dimension D10 of the second straight parts 43 along the second direction Y is less than a dimension D9 of the first straight parts 41 along the second direction Y.

The dimension D10 of the second straight parts 43 along the second direction Y is less than the dimension D9 of the first straight parts 41 along the second direction Y, so that the diagonal parts 42 connected between the second straight parts 43 and the first straight parts 41 extend along a direction proximate to a center line O of the fourth surface 8b, therefore, a region corresponding to the diagonal parts 42 forms a fan-out region SS of the back electrodes 4. In this way, the second straight parts 43 converge inward relative to the first straight parts 41, and a region corresponding to the second straight parts 43 is less than a region corresponding to the first straight parts 41, which is beneficial to an electrical connection of the flexible circuit board 9.

For example, as shown in FIG. 20, the minimum value of a dimension D11 of the bridge structure 8 along the second direction Y is the dimension D9 of the first straight parts 41 along the second direction Y. The maximum value of the dimension D11 of the bridge structure 8 along the second direction Y is M −30 μm, where M is a dimension of the substrate 1 along the second direction Y.

For example, as shown in FIG. 20, a dimension D12 of the bridge structure 8 along the third direction Z is in a range of 3 mm to 50 mm; this dimension range is reasonably selected, so that the area of the fourth surface 8b of the bridge structure 8 is sufficient to make the diagonal parts 42 form the fan-out region SS of the back electrodes 4. The dimension D12 of the bridge structure 8 along the third direction Z is, for example, 3 mm, 10 mm, 20 mm, 30 mm, 35 mm, 40 mm, or 50 mm.

In some examples, the second straight part 43 is directly electrically connected to the flexible circuit board 9 as shown in FIGS. 1 and 20, or the second straight part 43 is electrically connected to the flexible circuit board 9 through external leads. The flexible circuit board 9 is, for example, a chip on film (COF) flexible circuit board 9.

In some examples, as shown in FIG. 21, there is a fourth spacing L4 between an edge of the first straight part 41 proximate to the selected first side surface 1cc and an intersection line of the selected second side surface 8cc and the fourth surface 8b, and a value of the fourth spacing L4 is in a range of 0 to 1 mm. The fourth spacing L4 is, for example, 0 mm, 0.5 mm, or 1 mm.

For example, as shown in FIG. 21, a length D13 of the first straight part 41 along an extension direction thereof is greater than or equal to 60 μm. The length D13 of the first straight part 41 along the extension direction thereof is, for example, 60 μm, 80 μm, or 90 μm.

For example, as shown in FIG. 21, a dimension D14 of the first straight part 41 along the second direction Y is greater than 50 μm. The dimension D14 of the first straight part 41 along the second direction Y is, for example, 55 μm, 60 μm, or 70 μm.

For example, as shown in FIG. 21, a distance D15 between two adjacent first straight parts 41 is greater than or equal to 100 μm.

By such a setting, a short circuit between two adjacent first straight parts 41 may be prevented, and a sufficient space may be left to allow the protective layer 6 to be filled therein, so as to ensure the protective effect of the protective layer 6. The distance between two adjacent first straight parts 41 is, for example, 100 μm, 120 μm, or 150 μm.

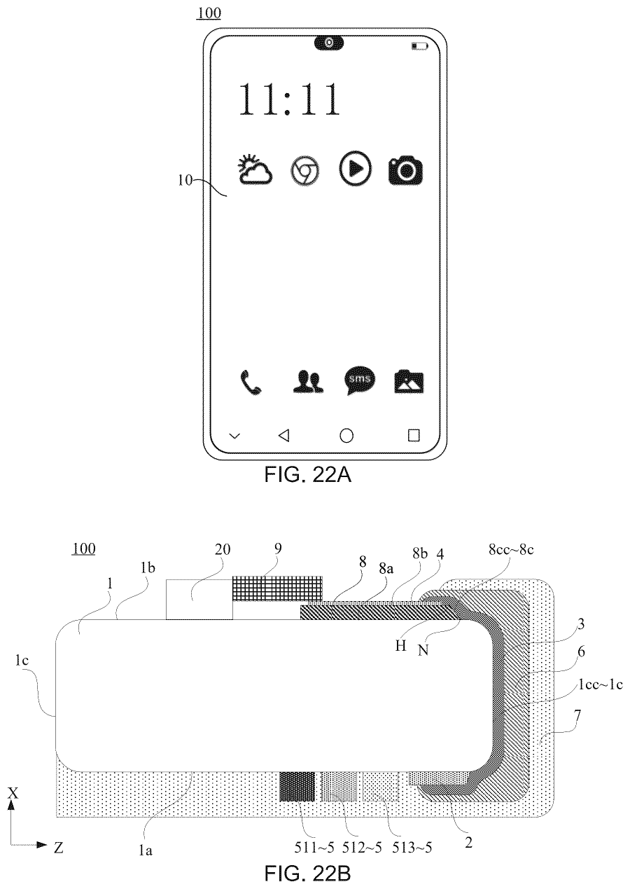

In another aspect, as shown in FIGS. 22A and 22B, a display device 100 is provided, which includes the display plane 10 provided in any of the embodiments and a driving circuit board 20. The driving circuit board 20 is electrically connected to the display panel 10. For example, the driving circuit board 20 is electrically connected to the back electrodes of the display panel 10 through the flexible circuit board 9, and electrical signals provided by the driving circuit board 20 are transmitted, via the flexible circuit board 9, the back electrodes 4, the connecting leads 3 and the front electrodes 2, to the driving circuit layer of the display panel 10 to control the light-emitting devices to emit light. The driving circuit board 20 is configured to drive the display panel 10 to display images.

The display device 100 may be any device that displays whether motion (e.g., videos), stationary (e.g., still images), text or image. More specifically, it is expected that the embodiments may be implemented in or associated with a variety of electronic devices. The variety of electronic devices are, for example, (but are not limited to), mobile telephones, wireless devices, personal data assistants (PDA), hand-held or portable computers, GPS receivers/navigators, cameras, MP4 video players, video cameras, game consoles, watches, clocks, calculators, TV monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as a display for an image of a piece of jewelry), and the like.

For example, the display device 100 may further include a frame and other electronic accessories. The display panel 10 may be disposed within the frame.

In yet another aspect, a titled display device 1000 is provided, which includes a plurality of display devices 100 each provided in any of the embodiments.

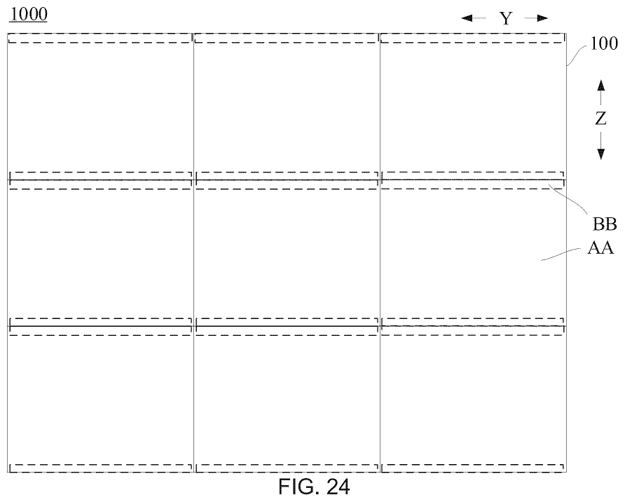

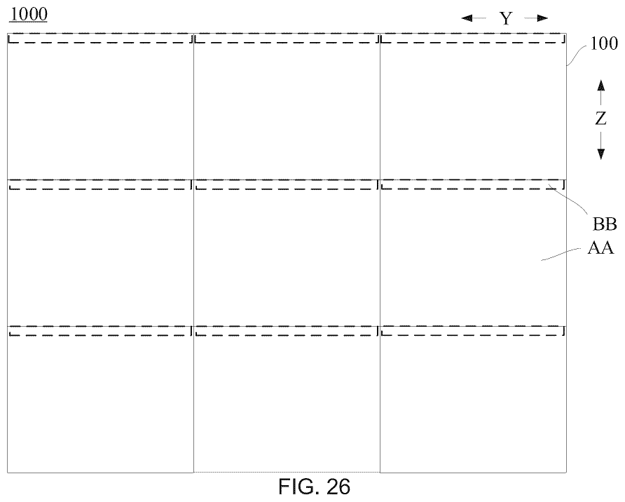

For example, as shown in FIGS. 24 and 26, the plurality of display devices 100 in the titled display devices 1000 are arranged in an array.

For example, as shown in FIGS. 24 and 26, the display device 100 is in a shape of a rectangle.

In the display panel 10, the plurality of front electrodes 2 are arranged side by side at intervals along the second direction Y. Correspondingly, the plurality of connecting leads 3 are also arranged side by side at intervals along the second direction Y. The third direction Z is parallel to the display device 100, and is another direction perpendicular to the second direction Y. The display device 100 includes a plurality of side surfaces. In the following description, a side surface proximate to the plurality of front electrodes 2 in the plurality of side surfaces of the display device 100 refers to as a selected side surface of the display device 100.

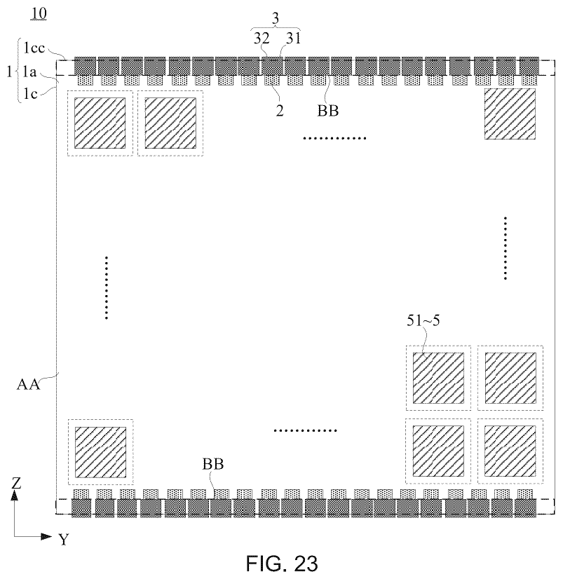

For example, as shown in FIG. 23, the display panel 10 includes a display area AA and two bonding areas BB located on opposite sides of the display area AA. The display panel 10 includes two groups of front electrodes 2, and each group of front electrodes 2 includes multiple front electrodes 2, and two groups of front electrodes 2 are respectively disposed proximate to the two bonding areas BB.

Further, as shown in FIG. 24, when the plurality of display devices 100 each including the display panel 10 as shown in FIG. 23 are spliced, selected side surfaces of two adjacent display devices 100 are arranged along the second direction Y, in this way, in multiple display devices 100 arranged in a row along the second direction Y, there is basically no splicing seam between two adjacent display devices 100 along the second direction Y; and in multiple display devices 100 arranged in a column along the third direction Z, there is a splicing seam between two adjacent display devices 100. That is to say, in the multiple display devices 100 arranged in a row along the second direction Y, a dimension of the splicing seam between two adjacent display devices 100 is less than a dimension of the splicing seam between two adjacent display devices 100 in the multiple display devices 100 arranged in a column along the third direction Z.

Since dimensions of the bonding areas BB in the third direction Z are very small, when the tiled display device 1000 is actually viewed, the splicing seam between two adjacent display devices 100 is difficult to be detected with the naked eye within the viewing distance, thereby making an image displayed by the tiled display device 1000 relatively complete and presenting a better display effect.

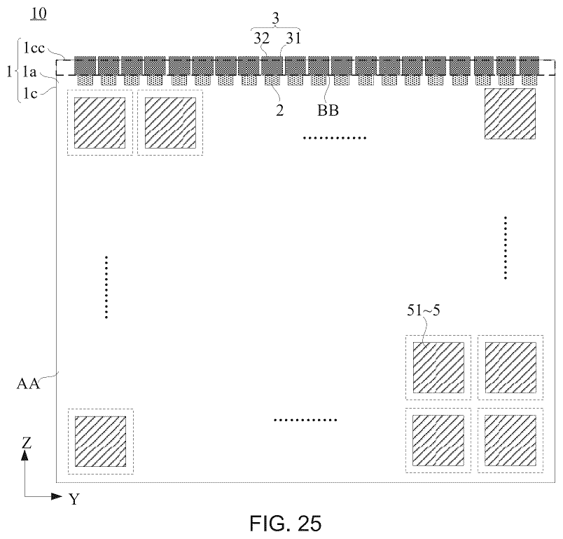

For example, as shown in FIG. 25, the display panel 10 includes a display area AA and a bonding area BB located on a side of the display area AA, and a plurality of front electrodes 2 are disposed in the bonding area BB.

Further, as shown in FIG. 26, when the plurality of display devices 100 each including the display panel 10 as shown in FIG. 25 are spliced, selected side surfaces of two adjacent display devices 100 are arranged along the second direction Y, in this way, in multiple display devices 100 arranged in a row along the second direction Y, there is basically no splicing seam between two adjacent display devices 100 along the second direction Y; and in multiple display devices 100 arranged in a column along the third direction Z, there is a splicing seam between two adjacent display devices 100. That is to say, in the multiple display devices 100 arranged in a row along the second direction Y, a dimension of the splicing seam between two adjacent display devices 100 is less than a dimension of the splicing seam between two adjacent display devices 100 in the multiple display devices 100 arranged in a column along the third direction Z.

Since dimensions of the bonding areas BB in the third direction Z are very small, when the tiled display device 1000 is actually viewed, the splicing seam between two adjacent display devices 100 is difficult to be detected with the naked eye within the viewing distance, thereby making an image displayed by the tiled display device 1000 relatively complete and presenting a better display effect.

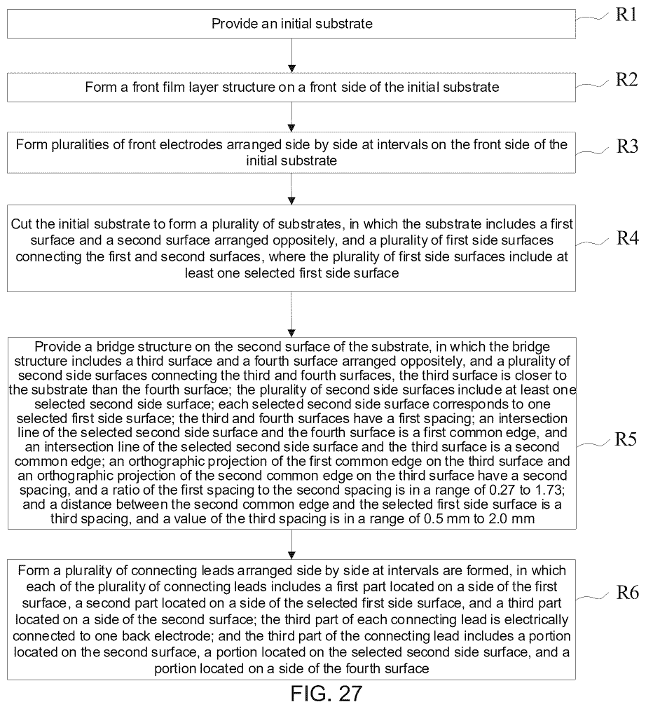

In still another aspect, a manufacturing method of a display panel 10 is provided. As shown in FIG. 27, the manufacturing method of the display panel 10 includes steps (R1 to R6).

In R1, an initial substrate is provided.

In R2, a front film layer structure is formed on a front side of the initial substrate.

For example, the front film layer structure includes a driving circuit layer.

In R3, pluralities of front electrodes 2 arranged side by side at intervals are formed on the front side of the initial substrate.

In R4, the initial substrate is cut to form a plurality of substrates 1. The substrate 1 includes a first surface 1a and a second surface 1b arranged oppositely, and a plurality of first side surfaces 1c connecting the first surface 1a and the second surface 1b, in which the plurality of first side surfaces 1c include at least one selected first side surface 1cc.

The film layer structures such as the front electrodes 2 and the driving circuit layer are all arranged on a front side of the substrate 1. The front electrodes 2 are proximate to the selected first side surface 1cc.

In R5, a bridge structure 8 is provided on the second surface 1b of the substrate 1. The bridge structure 8 includes a third surface 8a and a fourth surface 8b arranged oppositely, and a plurality of second side surfaces 8c connecting the third surface 8a and the fourth surface 8b, in which the third surface 8a is closer to the substrate 1 than the fourth surface 8b; the plurality of second side surfaces 8c include at least one selected second side surface 8cc; each selected second side surface 8cc corresponds to one selected first side surface 1cc. The third surface 8a and the fourth surface 8b have a first spacing L1. An intersection line of the selected second side surface 8cc and the fourth surface 8b is a first common edge H, and an intersection line of the selected second side surface 8cc and the third surface 8a is a second common edge N. An orthographic projection of the first common edge H on the third surface 8a and an orthographic projection of the second common edge N on the third surface 8a have a second spacing L2, and a ratio of the first spacing L1 to the second spacing L2 is in a range of 0.27 to 1.73. A distance between the second common edge N and the selected first side surface is a third spacing L3, and a value of the third spacing L3 is in a range of 0.5 mm to 2.0 mm.

A process of connecting the bridge structure 8 to the fourth surface 8b of the substrate 1 is, for example, a high-precision attachment, enabling the back electrodes 4 to be directly opposite to the front electrodes 2 in the first direction X.

Before R5, a plurality of back electrodes 4 are formed on the fourth surface 8b of the bridge structure 8, the plurality of back electrodes 4 being proximate to the selected second side surface 8cc. For example, a wet etching process is used to form the plurality of back electrodes.

In R6, a plurality of connecting leads 3 arranged side by side at intervals are formed. Each connecting lead 3 of the plurality of connecting leads 3 includes a first part 31 located on a side of the first surface 1a, a second part 32 located on a side of the selected first side surface 1cc, and a third part 33 located on a side of the second surface 1b. The third part 33 of each connecting lead 3 is electrically connected to one back electrode 4. The third part 33 of the connecting lead 3 includes a portion located on the second surface 1b, a portion located on the selected second side surface 8cc, and a portion located on a side of the fourth surface 8b.

For example, a process of forming the plurality of connecting leads 3 is a printing process. The printing process is, for example, screen printing, pad printing, transfer printing, or 3D printing.

In some embodiments, after R6, the manufacturing method of the display panel 10 further includes steps (R7 and R8).

In R7, a protective layer 6 is formed on a side of the connecting leads 3 away from the selected second side surface 8cc.

In R8, a light-blocking layer 7 is formed on a side of the protective layer 6 away from the selected second side surface 8cc and a side of the first surface 1a of the substrate 1.

In some other embodiments, in a case where the bridge structure 8 includes a circuit board 81 and a buffer structure 82, R4 includes steps (R4.1 and R4.2).

In R4.1, the circuit board 81 is attached to the second surface 1b of the substrate 1.

A process of connecting the circuit board 81 to the fourth surface 8b of the substrate 1 is, for example, a high-precision attachment, enabling the back electrodes 4 to be directly opposite to the front electrodes 2 in the first direction X.

In R4.2, the buffer structure 82 is formed on a side surface of the circuit board 81 proximate to the selected first side surface 1cc.

A process of forming the buffer structure 82 is, for example, screen printing, pad printing, transfer printing, or 3D printing.

The manufacturing processes such as a printing process, are only described as examples and are not intended to limit the actual production process.

The foregoing description is only specific embodiments of the present disclosure, but the scope of protection of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a substrate, including a first surface and a second surface arranged oppositely, and a plurality of first side surfaces connecting the first surface and the second surface, wherein the plurality of first side surfaces include at least one selected first side surface;
a bridge structure, disposed on the second surface and including a third surface and a fourth surface arranged oppositely, and a plurality of second side surfaces connecting the third surface and the fourth surface, the third surface being closer to the substrate than the fourth surface, wherein the plurality of second side surfaces include at least one selected second side surface, and each selected second side surface corresponds to one selected first side surface; and the third surface and the fourth surface have a first spacing;
a plurality of back electrodes, arranged side by side at intervals on the fourth surface; and
a plurality of connecting leads, arranged side by side at intervals, wherein each connecting lead includes a first portion located on a side of the first surface, a second portion located on a side of the selected first side surface, and a third portion located on a side of the second surface; and the third part of each connecting lead is electrically connected to one back electrode, and the third part of the connecting lead includes a portion located on the second surface, a portion located on the selected second side surface, and a portion located on a side of the fourth surface;
wherein a first common edge is an intersection line of the selected second side surface and the fourth surface, and a second common edge is an intersection line of the selected second side surface and the third surface; and an orthographic projection of the first common edge on the third surface and an orthographic projection of the second common edge on the third surface have a second spacing, and a ratio of the first spacing to the second spacing is in a range of 0.27 to 1.73; and
a distance between the second common edge and the selected first side surface is a third spacing, and a value of the third spacing is in a range of 0.5 mm to 2.0 mm.

2. The display panel according to claim 1, wherein the portion of the third part of the connecting lead corresponding to the fourth surface has a first thickness, the portion of the third part of the connecting lead corresponding to the second surface has a second thickness, and the portion of the third part of the connecting lead corresponding to the selected second side surface has a third thickness;
wherein the first thickness is greater than or equal to the second thickness, and a difference between the first thickness and the second thickness is in a range of 0 to 1 μm; and the third thickness is greater than the first thickness or the second thickness, and a difference between the third thickness and the first thickness, or a difference between the third thickness and the second thickness is in a range of 1 μm to 3 μm.

3. The display panel according to claim 1, wherein a section of the selected second side surface perpendicular to the first common edge or the second common edge is in a shape of a straight segment, a curved segment, or a polyline segment, the curved segment being bent away from the second surface.

4. The display panel according to claim 1, wherein the selected second side surface is a plane, and an included angle between the selected second side surface and the third surface is in a range of 10° to 80°.

5. The display panel according to claim 1, wherein the selected second side surface includes a plurality of sub-surfaces connected in sequence;
wherein in two adjacent sub-surfaces, a sub-surface further away from the selected first side surface is further away from the second surface than the other sub-surface.

6. The display panel according to claim 5, wherein the plurality of sub-surfaces are planes, and the selected second side surface is in a stepped shape; and
the plurality of sub-surface of the selected second side surface include at least two first sub-surfaces and at least one second sub-surface that are arranged alternately; and in the plurality of sub-surfaces, a sub-surface closest to the fourth surface and a sub-surface closest to the second surface are both first sub-surfaces;
wherein the at least two first sub-surfaces are parallel to the selected first side surface; and/or
the at least one second sub-surface is parallel to the second surface.

7. The display panel according to claim 6, wherein in a first direction, a dimension of an orthographic projection of each of the at least two first sub-surfaces on a first reference plane is a first dimension, the first reference plane being parallel to the selected first side surface, and the first direction being a thickness direction of the substrate; and/or
in a third direction, a dimension of an orthographic projection of the at least one second sub-surface on a second reference plane is a second dimension, the second reference plane being parallel to the second surface, and the third direction being perpendicular to the selected first side surface.

8. The display panel according to claim 1, wherein the bridge structure includes:
a circuit board, including a fifth surface and a sixth surface arranged oppositely, and a plurality of third side surfaces connecting the fifth surface and the sixth surface, wherein the plurality of third side surfaces include at least one selected third side surface, the at least one selected third side surface serving as the at least one selected second side surface; and the plurality of back electrodes are arranged side by side at intervals on the sixth surface.

9. The display panel according to claim 8, wherein the circuit board includes an adhesive layer and a carrier board body disposed in stack, the adhesive layer being closer to the substrate than the carrier board body; and
the selected third side surface of the circuit board is in a stepped shape, and a distance between an end of the carrier board body proximate to the selected first side surface and the selected first side surface greater than a distance between an end of the adhesive layer proximate to the selected first side surface and the selected first side surface.

10. The display panel according to claim 9, wherein a ratio of a thickness of the adhesive layer to a thickness of the carrier board body is in a range of 1.4 to 1.6.

11. The display panel according to claim 1, wherein the bridge structure includes:
a circuit board, including a fifth surface and a sixth surface arranged oppositely, and a plurality of third side surfaces connecting the fifth surface and the sixth surface, wherein the plurality of back electrodes are arranged side by side at intervals on the sixth surface; and
a buffer structure, located on a side of the circuit board proximate to the selected first side surface, wherein an outer surface of the buffer structure serves as at least a portion of the selected second side surface, and the outer surface of the buffer structure is a surface of the buffer structure away from the circuit board and the second surface.

12. The display panel according to claim 11, wherein the buffer structure includes a plurality of first buffer sub-structures, and at least a portion of each connecting lead is disposed on a corresponding first buffer sub-structure of the plurality of first buffer sub-structures.

13. The display panel according to claim 11, wherein the plurality of connecting leads include multiple groups of connecting leads, each group of connecting leads including at least two connecting leads; and the buffer structure includes a plurality of second buffer sub-structures, and at least a portion of each group of connecting leads is disposed on a corresponding second buffer sub-structure in the plurality of second buffer sub-structures.

14. The display panel according to claim 11, wherein the buffer structure extends along a second direction, the second direction being an extension direction of a boundary line between the selected first side surface and the second surface; and a length of the buffer structure is greater than a distance between outer side edges of two connecting leads of the plurality of connecting leads whose orthographic projections on the second surface are located outermost, the outer side edges of the two connecting leads being side edges of the two connecting leads away from each other.

15. The display panel according to claim 11, wherein a section, perpendicular to the first common edge or the second common edge, of a surface of the buffer structure away from the circuit board and the second surface is in a shape of a straight segment, a curved segment or a polyline segment, the curved segment being bent away from the second surface; or the surface of the buffer structure away from the circuit board and the second surface includes a plurality of sub-surfaces connected in sequence.

16. The display panel according to claim 11, wherein the buffer structure covers a junction of a side surface of the circuit board proximate to the selected first side surface and the sixth surface of the circuit board.

17. (canceled)

18. The display panel according to claim 1, wherein the portion of the connecting lead located on the second surface has an end proximate to the bridge structure, and a dimension of the end in a second direction is greater than dimensions of the remaining portions of the connecting lead in the second direction, the second direction being an extension direction of a boundary line between the selected first side surface and the second surface.

19. The display panel according to claim 1, wherein each back electrode includes:
a first straight part, extending along a direction perpendicular to a second direction, the second direction being an extension direction of a boundary line between the selected first side surface and the second surface;
a diagonal part, connected to the first straight part, wherein the extension direction of the first straight part intersects an extension direction of the diagonal part; and
a second straight part, connected to the diagonal part and extending along the direction perpendicular to the second direction, wherein the second straight part is further away from the selected first side surface than the first straight part;
wherein the first straight part is electrically connected to a third part of a connecting lead, and the second straight part is configured to connect a flexible circuit board; and
first straight parts of the plurality of back electrodes are arranged along the second direction, second straight parts of the plurality of back electrodes are arranged along the second direction, and a dimension of the second straight parts along the second direction is less than a dimension of the first straight parts along the second direction.

20. A display device, comprising:
the display panel according to claim 1; and
a driving circuit board, electrically connected to the display panel and configured to drive the display panel to display an image.

21. A titled display device, comprising a plurality of display devices each according to claim 20.
